(19) United States
(12) Patent Application Publication
(10) Pub. No.: US 2012/0126205 A1
(43) Pub. Date: May 24, 2012

(54) ORGANIC ELECTROLUMINESCENCE DEVICE

(75) Inventors: Yuichiro Kawamura, Sodegaura-shi (JP); Hiroyuki Saito, Sodegaura-shi (JP); Hitoshi Kuma, Sodegaura-shi (JP); Masahiro Kawamura, Sodegaura-shi (JP); Yukitoshi Jinde, Sodegaura-shi (JP); Hirokatsu Ito, Sodegaura-shi (JP)

(73) Assignee: Idemitsu Kosan Co., Ltd.

(21) Appl. No.: 13/017,978

(22) Filed: Jan. 31, 2011

(30) Foreign Application Priority Data
Nov. 22, 2010 (JP) 2010-260674

(51) Int. Cl. H01L 51/52; H01L 51/54

(52) U.S. Cl. 257/40; 257/E51.018; 257/E51.024

(57) ABSTRACT

An organic electroluminescence device includes an anode, an emitting layer, a blocking layer, an electron injecting layer, and a cathode in sequential order. The emitting layer includes a host and dopant. The blocking layer includes an aromatic heterocyclic derivative. A triplet energy E^{T}_{b} (eV) of the blocking layer is larger than a triplet energy E^{T}ₕ (eV) of the host. An affinity A_{b} (eV) of the blocking layer and an affinity A_{b} (eV) of the electron injecting layer satisfy a relationship of Aₑ−A_{b}<0.2.

The entire disclosure of Japanese Patent Application No. 2010-260674 filed Nov. 22, 2010 is expressly incorporated by reference herein.

### BACKGROUND OF THE INVENTION

1. Field of the Invention

The present invention relates to an organic electroluminescence device.

2. Description of Related Art

An organic electroluminescence device (hereinafter, referred to as organic EL device) can be classified by the emission principle into two types: a fluorescent EL device and a phosphorescent EL device. When a voltage is applied to the organic EL device, holes are injected from an anode and electrons are injected from a cathode. The holes and the electrons are recombined in an emitting layer to form excitons. According to the electron spin statistics theory, singlet excitons and triplet excitons are generated at a ratio of 25%:75%. In a fluorescent EL device which uses emission caused by singlet excitons, the limited value of an internal quantum efficiency is believed to be 25%. A technology for extending a lifetime of a fluorescent EL device using a fluorescent material has recently been improved and applied to a full-color display of a mobile phone, TV and the like. However, a fluorescent EL device is required to be improved in efficiency.

In association with the technology for bringing efficiency to the fluorescent EL device, several technologies are disclosed in which emission is obtained from triplet excitons, which have heretofore been not utilized effectively. For instance, in Non-Patent Literature 1 (Journal of Applied Physics, 102, 114504 (2007)), a non-doped device, in which an anthracene compound is used as a host, is analyzed. A mechanism is found that singlet excitons are generated by collision and fusion of two triplet excitons, whereby fluorescent emission is increased. Such a phenomenon in which singlet excitons are generated by collision and fusion of two triplet excitons is hereinafter referred to as TTF (Triplet-Triplet Fusion) phenomenon.

In Non-Patent Literature 2 (SID10 DIGEST, 560 (2010)) discloses a blue-emission fluorescent OLED in which a layer of an aromatic compound (efficiency-enhancement layer, referred to as EEL) is interposed between an emitting layer including a host and a dopant and an electron transporting layer. It is reported that an OLED in which a compound EEL-1 is used as EEL is driven by a low voltage, exhibits a high external quantum efficiency and has a long lifetime compared with an OLED in which BPhen or BCP is used as EEL. This EEL can serve as a blocking layer for causing a TTF phenomenon.

However, Non-Patent Document 1 discloses only that fluorescent emission is increased by collision and fusion of triplet excitons in a non-doped device in which only a host is used. In this technology, an increase in efficiency by triplet excitons is as low as 3 to 6%.

Non-Patent Document 2 reports that the external quantum efficiency (EQE) of the device using BCP as EEL is inferior to a device using EEL-1 as EEL by tens of %. It has been considered difficult to satisfy a predetermined relationship of triplet energy and to efficiently cause a TTF phenomenon by using a compound (e.g. BCP) including a hetero atom in a blocking layer, thereby preparing a highly efficient device.

### SUMMARY OF THE INVENTION

An object of the invention is to provide an organic EL device of a fluorescent emission with high efficiency.

As a result of the studies, the inventors have found as follows.

In an organic EL device in which a blocking layer is interposed between an emitting layer and an electron injecting layer, when there is a difference between an affinity of the electron injecting layer and an affinity of the blocking layer, an energy barrier is formed on an interface between the electron injecting layer and the blocking layer. When the energy barrier is large, electrons injected from the cathode cannot sufficiently be supplied to the emitting layer, whereby holes and electrons are not sufficiently recombined in the emitting layer. Thus, it has been found that a presence of the energy barrier hampers sufficient generation of excitons contributing to a TTF phenomenon.

Initially, the inventors have found that, by setting a value obtained by subtracting an affinity A_{b} of the blocking layer from an affinity Aₑ of the electron injecting layer to be less than 0.2 eV, the electrons supplied from the cathode can break into the energy barrier formed on the interface between the electron injecting layer and the blocking layer, thereby sufficiently supplying the electrons into the emitting layer.

Based on these foundings, the inventors achieved the invention of an organic EL device as follows.

An organic electroluminescence device according to an aspect of the invention includes an anode, an emitting layer, a blocking layer, an electron injecting layer, and a cathode in sequential order, in which the blocking layer includes an aromatic heterocyclic derivative, a triplet energy E^{T}_{b} (eV) of the aromatic heterocyclic derivative is larger than a triplet energy E^{T}ₕ (eV) of the host, and an affinity A_{b} (eV) of the blocking layer and an affinity Aₑ (eV) of the electron injecting layer satisfy a relationship of Aₑ−A_{b}<0.2.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.2<E^{T}_{b}.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.3<E^{T}_{b}.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.4<E^{T}_{b}.

In the organic EL device according to the above aspect of the invention, it is preferable that the aromatic heterocyclic derivative included in the blocking layer has six or more cyclic structures, and the triplet energy E^{T}_{b} (eV) of the aromatic heterocyclic derivative having the six or more cyclic structures is larger than a triplet energy E^{T}ₕ (eV) of the host.

In the organic EL device according to the above aspect of the invention, it is preferable that the triplet energy E^{T}_{b} (eV) of the aromatic heterocyclic derivative and the triplet energy E^{T}_{Alq} (eV) of tris(8-quinolinolato)aluminum complex satisfy a relationship of E^{T}_{b}>E^{T}_{Alq}.

In the organic EL device according to the above aspect of the invention, it is preferable that an electron mobility of the aromatic heterocyclic derivative in the blocking layer is 10⁻⁶ cm²/Vs or more in an electric field intensity of 0.04 MV/cm to 0.5 MV/cm.

In the organic EL device according to the above aspect of the invention, it is preferable that an electron mobility of a material for forming the electron injecting layer is 10⁻⁶ cm²/Vs or more in an electric field intensity of 0.04 MV/cm to 0.5 MV/cm.

In the organic EL device according to the above aspect of the invention, it is preferable that the dopant exhibits a fluorescent emission of a main peak wavelength of 550 nm or less, and a triplet energy E^{T}_{d} (eV) of the dopant is larger than a triplet energy E^{T}ₕ (eV) of the host.

In the organic EL device according to the above aspect of the invention, it is preferable that a hole transporting zone is provided between the anode and the emitting layer, a hole transporting layer is adjacent to the emitting layer in the hole transporting zone, and a triplet energy E^{T}ₕₒ (eV) of the hole transporting layer is larger than the triplet energy E^{T}ₕ (eV) of the host.

In the organic EL device according to the above aspect of the invention, it is preferable that a material for forming the electron injecting layer is the same as a material for forming the blocking layer.

In the organic EL device according to the above aspect of the invention, it is preferable that a material for forming the electron injecting layer is the same as a material for forming the blocking layer, and doped with a donor.

In the organic EL device according to the above aspect of the invention, it is preferable that the dopant is at least one compound selected from the group consisting of a pyrene derivative, aminoanthracene derivative, aminochrysene derivative, aminopyrene derivative, fluoranthene derivative and boron complex.

In the organic EL device according to the aspect of the invention, it is preferable that the host is a compound that contains a double bond only in a cyclic structure.

In the organic EL device according to the aspect of the invention, it is preferable that the dopant is a compound that contains a double bond only in a cyclic structure.

On the other hand, the inventors found out that, with use of a compound having an azine ring in the blocking layer, a highly efficient organic EL device can be prepared even when the energy barrier exists between the blocking layer and the electron injecting layer (i.e., when a difference in affinity is not 0.2 or less, unlike the above).

In other words, even when the energy barrier exists between the blocking layer and the electron injecting layer, a compound having a high electron mobility, particularly, a compound having an azine ring is unlikely to be vulnerable to the energy barrier, so that an amount of the electrons supplied to the emitting layer is hardly decreased. Consequently, a highly efficient device by the TTF phenomenon has been achieved.

Based on these foundings, the inventors achieved the invention of an organic EL device as follows.

An organic electroluminescence device according to another aspect of the invention includes an anode, an emitting layer, a blocking layer, an electron injecting layer, and a cathode in sequential order, in which the emitting layer includes a host and a dopant, a triplet energy E^{T}ₕ (eV) of the aromatic heterocyclic derivative is larger than a triplet energy E^{T}ₕ (eV) of the host, and the aromatic heterocyclic derivative has an azine ring.

In the organic EL device according to the aspect of the invention, the aromatic heterocyclic derivative is represented by a formula (BL-21) below,

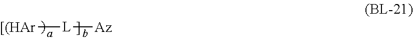

where: HAr is a substituted or unsubstituted heterocyclic group having 5 to 30 atoms forming a ring, and when a plurality of HAr are present, the plurality of HAr are mutually the same or different;

Az represents a substituted or unsubstituted pyrimidine, a substituted or unsubstituted pyrazine, a substituted or unsubstituted pyridazine, or a substituted or unsubstituted triazine;

L represents a single bond, a divalent to tetravalent residue of a substituted or unsubstituted aromatic hydrocarbon ring having 6 to 30 ring carbon atoms, a divalent to tetravalent residue of a substituted or unsubstituted heterocylic ring having 5 to 30 ring atoms, or a divalent to tetravalent residue formed by combination in a single bond of two to three rings selected from the aromatic hydrocarbon ring and the heterocyclic ring; a is an integer of 1 to 3; and b is an integer of 1 to 3.

In the organic EL device according to the above aspect of the invention, it is preferable that an electron mobility of the aromatic heterocyclic derivative in the blocking layer is 10⁻⁶ cm²/Vs or more in an electric field intensity of 0.04 MV/cm to 0.5 MV/cm.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.2<E^{T}_{b}.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.3<E^{T}_{b}.

In the organic EL device according to the above aspect of the invention, it is preferable that the triplet energy E^{T}_{b} (eV) of the aromatic heterocyclic derivative and the triplet energy E^{T}ₕ (eV) of the host satisfy a relationship of E^{T}ₕ+0.4<E^{T}_{b}.

In the organic EL device according to the above aspect of the invention, it is preferable that the aromatic heterocyclic derivative included in the blocking layer has six or more cyclic structures, and the triplet energy E^{T}_{b} (eV) of the aromatic heterocyclic derivative having the six or more cyclic structures is larger than a triplet energy E^{T}ₕ (eV) of the host.

In the organic EL device according to the above aspect of the invention, it is preferable that an electron mobility of a material for forming the electron injecting layer is 10⁻⁶ cm²/Vs or more in an electric field intensity of 0.04 MV/cm to 0.5 MV/cm.

In the organic EL device according to the above aspect of the invention, it is preferable that the dopant exhibits a fluorescent emission of a main peak wavelength of 550 nm or less, and the triplet energy E^{T}_{d} (eV) of the dopant is larger than a triplet energy E^{T}ₕ (eV) of the host.

In the organic EL device according to the above aspect of the invention, it is preferable that a hole transporting zone is provided between the anode and the emitting layer, a hole transporting layer is adjacent to the emitting layer in the hole transporting zone, and a triplet energy E^{T}ₕₒ (eV) of the hole transporting layer is larger than the triplet energy E^{T}ₕ (eV) of the host.

In the organic EL device according to the above aspect of the invention, it is preferable that a material for forming the electron injecting layer is the same as a material for forming the blocking layer.

In the organic EL device according to the above aspect of the invention, it is preferable that a material for forming the electron injecting layer is the same as a material for forming the blocking layer, and doped with a donor.

In the organic EL device according to the above aspect of the invention, it is preferable that the dopant is at least one compound selected from the group consisting of a pyrene derivative, aminoanthracene derivative, aminochrysene derivative, aminopyrene derivative, fluoranthene derivative and boron complex.

In the organic EL device according to the aspect of the invention, it is preferable that the host is a compound that contains a double bond only in a cyclic structure.

In the organic EL device according to the aspect of the invention, it is preferable that the dopant is a compound that contains a double bond only in a cyclic structure.

According to the above aspect of the invention, the TTF phenomenon efficiently occurs, thereby providing an organic EL device of a fluorescent emission with a high efficiency.

### BRIEF DESCRIPTION OF THE DRAWINGS

FIG. 1 is a view showing one example of an organic EL device according to a first exemplary embodiment of the invention.

FIG. 2 is a view showing a relationship of energy gaps between layers of the invention.

FIG. 3 is a view showing an action based on the relationship of the energy gaps between the layers of the invention.

FIG. 4 is an energy band diagram showing a case where an affinity of a host (Ah)>an affinity of a dopant (Ad) is satisfied.

FIG. 5 is an energy band diagram showing a case where Ah<Ad is satisfied and a difference between Ah and Ad is less than 0.2 eV.

FIG. 6 is an energy band diagram showing a case where Ah<Ad is satisfied and a difference between Ah and Ad is more than 0.2 eV.

FIG. 7 is an energy band diagram showing a case where a dopant satisfying Ah<Ad and a dopant satisfying Ah>Ad coexist.

FIG. 8 is a view showing one example of an organic EL device according to a third exemplary embodiment.

FIG. 9 is a view showing one example of an organic EL device according to a fourth exemplary embodiment.

FIG. 10 is a view showing one example of an organic EL device according to a fifth exemplary embodiment.

### DETAILED DESCRIPTION OF PREFERRED EMBODIMENT(S)

### First Exemplary Embodiment

The invention utilizes a TTF phenomenon. The TTF phenomenon will be initially explained below.

Holes and electrons respectively injected from an anode and a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of a conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in the density thereof, whereby a reaction shown by the following formula occurs. In the formula, ¹A represents the ground state and ¹A* represents the lowest singlet excitons.

³A*+³A*→(4/9)¹A+(1/9)¹A*+(13/9)³A*

In other words, 5³A*4¹A+¹A*, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(1/5)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially-generated triplet excitons which account for 75% (i.e., one singlet exciton is generated from two triplet excitons), a significantly high internal quantum efficiency of 62.5% is obtained which is a value obtained by adding 37.5% (75%×(1/2)=37.5%) to 25%, which is the amount ratio of initially generated singlet excitons. At this time, the TTF ratio is 60% (37.5/62.5).

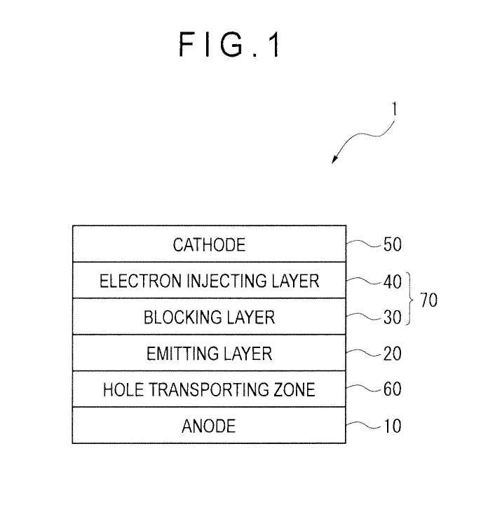

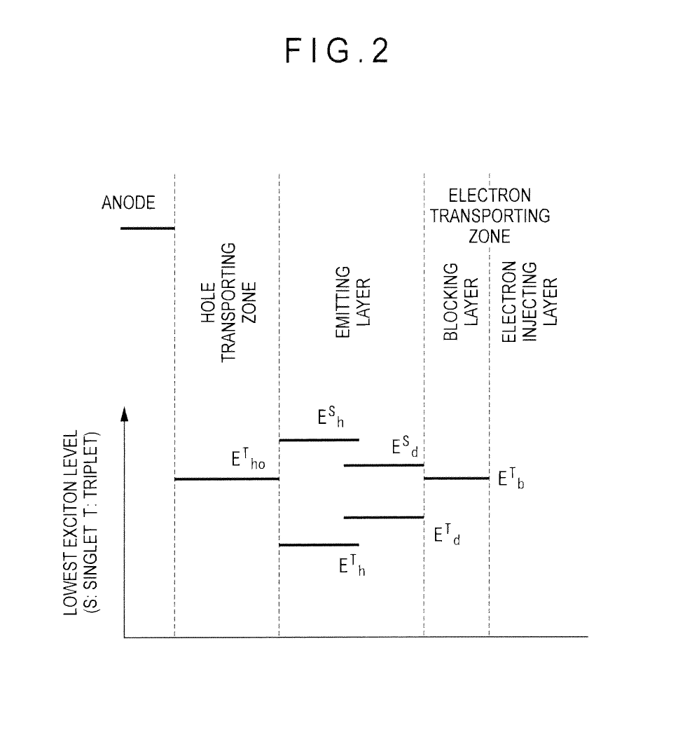

FIG. 1 is schematic view showing one example of an organic EL device according to a first exemplary embodiment of the invention. FIG. 2 is a schematic view showing a relationship between a triplet energy of the emitting layer and a triplet energy of an electron transporting zone in the organic EL device according to the first exemplary embodiment In the invention, the triplet energy is referred to as a difference between energy in the lowest triplet state and energy in the ground state. The singlet energy (often referred to as energy gap) is referred to as a difference between energy in the lowest singlet state and energy in the ground state.

The organic EL device 1 shown in FIG. 1 includes an anode 10, a hole transporting zone 60, an emitting layer 20, a blocking layer 30, an electron injecting layer 40, and a cathode 50 in sequential order. These components are adjacent to one another in the organic EL device of the invention. An electron transporting zone 70 includes the blocking layer 30 and the electron injecting layer 40. It is preferred that the hole transporting zone 60 is interposed between the anode 10 and the emitting layer 20. The hole transporting zone includes at least one of a hole injecting layer and a hole transporting layer. In the invention, a simply-called blocking layer means a layer functioning as a barrier against the triplet energy. Accordingly, the blocking layer functions differently from a hole blocking layer and a charge blocking layer.

The emitting layer includes a host and a dopant. As the dopant, a dopant emitting fluorescent light of a main peak wavelength of 550 nm or less (hereinafter occasionally referred to as a fluorescent dopant having a main peak wavelength of 550 nm or less) is preferable. A main peak wavelength means a peak wavelength of luminescence spectrum exhibiting a maximum luminous intensity among luminous spectra measured in a toluene solution with a concentration from 10⁻⁵ mol/l to 10⁻⁶ mol/l. The main peak wavelength of 550 nm is substantially equivalent to a green emission. In this wavelength zone, improvement in luminous efficiency of a fluorescent device utilizing the TTF phenomenon is desired. In a blue-emitting fluorescent device of 480 nm or less, further improvement in luminous efficiency is expectable. In a red-emitting fluorescent device of 550 nm or more, a phosphorescent device exhibiting a high internal quantum efficiency has already been at a practical level. Accordingly, improvement in luminous efficiency as a fluorescent device is not desired. In FIG. 2, the holes injected from the anode are injected to the emitting layer via the hole transporting zone. The electrons injected from the cathode are injected to the emitting layer via the electron injecting layer and the blocking layer. Subsequently, the holes and the electrons are recombined in the emitting layer to generate singlet excitons and triplet excitons. There are two manners as for the occurrence of recombination: recombination may occur either on host molecules or on dopant molecules.

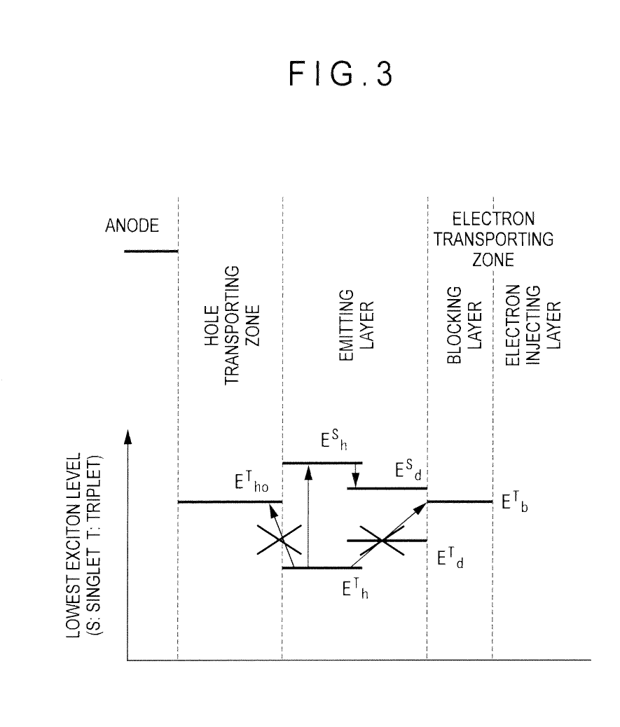

In this exemplary embodiment, as shown in FIG. 2, when the triplet energy of the host and that of the dopant are respectively taken as E^{T}ₕ and E^{T}_{d}, a relationship of E^{T}ₕ<E^{T}_{d} is satisfied. When this relationship is satisfied, triplet excitons generated by recombination on the host do not transfer to the dopant which has a higher triplet energy, as shown in FIG. 3. Triplet excitons generated by recombination on dopant molecules quickly energy-transfer to host molecules. In other words, triplet excitons on the host do not transfer to the dopant but collide with one another efficiently on the host to generate singlet excitons by the TTF phenomenon. Further, since the singlet energy E^{S}_{d} of the dopant is smaller than the singlet energy E^{S}ₕ of the host: a relationship of E^{S}ₕ<E^{S}_{d} is satisfied, singlet excitons generated by the TTF phenomenon energy-transfer from the host to the dopant, thereby contributing to fluorescent emission of the dopant. In dopants which are usually used in a fluorescent device, transition from the triplet state to the ground state should be inhibited. In such a transition, triplet excitons are not optically energy-deactivated, but are thermally energy-deactivated. By causing the triplet energy of the host and the triplet energy of the dopant to satisfy the above-mentioned relationship, the singlet excitons are generated efficiently due to the collision of the triplet excitons before they are thermally deactivated, whereby luminous efficiency is improved.

In the invention, the blocking layer is adjacent to the emitting layer. The blocking layer has a function of preventing triplet excitons generated in the emitting layer to be diffused to an electron transporting zone and confining the triplet excitons within the emitting layer to increase a density of the triplet excitons therein, thereby causing the TTF phenomenon efficiently.

The blocking layer also serves for efficiently injecting the electrons to the emitting layer. When the electron injecting properties to the emitting layer are deteriorated, the density of the triplet excitons is decreased since the electron-hole recombination in the emitting layer is decreased. When the density of the triplet excitons is decreased, the frequency of collision of the triplet excitons is reduced, whereby the TTF phenomenon does not occur efficiently.

In the invention, the blocking layer contains an aromatic heterocyclic derivative.

In this exemplary embodiment, in order to prevent the triplet excitons generated in the emitting layer from being diffused to the electron transporting zone and efficiently inject the electrons to the emitting layer, an affinity (A_{b}) of the blocking layer and an affinity (Aₑ) of the electron injecting layer satisfy a relationship of the following formula (1).

Aₑ−A_{b}<0.2 (1)

When the relationship is not satisfied, the electron injection from the electron injecting layer to the blocking layer becomes difficult.

Preferably, the affinity (A_{b}) of the blocking layer and the affinity (Aₑ) of the electron injecting layer satisfy a relationship of the following formula (2).

−3<Aₑ−A_{b}<0.2 (2)

A material for forming the electron injecting layer may be the same as that for forming the blocking layer. In this case, the electron injecting layer is preferably doped with a donor. Doping with the donor facilitates receiving the electrons from the cathode. Particularly, it is preferred that the electron injecting layer is doped with a donor represented by an alkali metal near an interface with the cathode. As the donor, at least one selected from the group consisting of a donor metal, a donor metal compound and a donor metal complex can be used. Specific donors will be described later.

In the invention, in order to prevent diffusion of triplet excitons, the triplet energy E^{T}_{b} of the aromatic heterocyclic derivative contained in the blocking layer is larger than the triplet energy E^{T}ₕ of the host. In other words, a relationship of E^{T}ₕ<E^{T}_{b} is satisfied.

It is preferred that the triplet energy E^{T}_{b} of the aromatic heterocyclic derivative is larger than the triplet energy E^{T}_{d} of the dopant. In other words, a relationship of E^{T}ₕ<E^{T}_{d} is satisfied.

Since the blocking layer prevents triplet excitons from being diffused to the electron injecting layer, in the emitting layer, triplet excitons of the host become singlet excitons efficiently, and the singlet excitons transfer to the dopant, and are optically energy-deactivated.

It is preferred that the triplet energy E^{T}_{b} of the aromatic heterocyclic derivative and the triplet energy E^{T}ₕ of the host satisfy a relationship of E^{T}ₕ+0.2<E^{T}_{b}.

E^{T}ₕ+0.2<E^{T}_{b}

It is more preferable that the triplet energy E^{T}_{b} of the aromatic heterocyclic derivative and the triplet energy E^{T}_{I}, of the host satisfy a relationship of E^{T}ₕ+0.3<E^{T}_{b}.

E^{T}ₕ+0.3<E^{T}_{b}

It is more preferable that the triplet energy E^{T}_{b} of the aromatic heterocyclic derivative and the triplet energy E^{T}ₕ of the host satisfy a relationship of E^{T}ₕ+0.4<E^{T}_{b}.

As described above, as the energy barrier of triplet energy becomes large, particularly when exceeding 0.2, the triplet excitons are difficult to be energetically balanced between the emitting layer and blocking layer due to thermal energy. In this case, in addition to diffusion to the blocking layer, deterioration in efficiency by a thermal deactivation mode is believed to be prevented. Accordingly, it is preferred that the above relationships are satisfied.

It is preferred that the triplet energy E^{T}_{b} of the blocking layer and the triplet energy E^{T}_{Alq} of tris(8-quinolinolato)aluminum complex satisfy a relationship of E^{T}_{b}>E^{T}_{Alq}.

By satisfying such a relationship, advantages to confine the triplet excitons within the emitting layer can be enhanced.

When the blocking layer contains an aromatic heterocyclic derivative having six or more cyclic structures, the luminous efficiency of the organic EL device is improved compared with Bphen and BCP having five or less cyclic structures. The reasons are as follows.

Bphen and BCP, which are known electron transporting materials having a high triplet energy, each exhibit a low film stability in a film formation due to its small molecular size. This means that, when these compounds are used as the blocking layer, a condition of an interface between the blocking layer and the electron injecting layer is easily changed, resulting in partial association of moleculars. Since the condition of the interface is changed by such association, it is considered that the electron supply from the electron injecting layer is hampered. As a result, it is considered that the exciton density within the emitting layer is lowered, which adversely influences improvement in luminous efficiency by the TTF phenomenon.

Formation of association can be avoided by increasing the molecular size to enhance film stability. In the invention, it is preferred that an aromatic heterocyclic derivative having a large cyclic-structure number, particularly having six or more cyclic structures, is used in the blocking layer. As a result, it is considered that the exciton density within the emitting layer is improved by allowing sufficient electron supply from the electron injecting layer without the formation of association, whereby the luminous efficiency is enhanced by the TTF phenomenon.

It will be described how to count a cyclic structure of the aromatic heterocyclic derivative. In the invention, one cyclic structure refers to a cyclic structure having one ring formed by a covalent bond of non-metal atoms in a molecule. Particularly, in the case of a fused ring group, the number of a fused cyclic structure is defined as the number of a cyclic structure of the fused ring group. For instance, a naphthalene ring has two cyclic structures and a dibezofuran ring has three cyclic structures. An aromatic heterocyclic derivative represented by the following chemical formula (1) has ten cyclic structures. Accordingly, this aromatic heterocyclic derivative is included in the aromatic heterocyclic derivative used in the blocking layer of the invention.

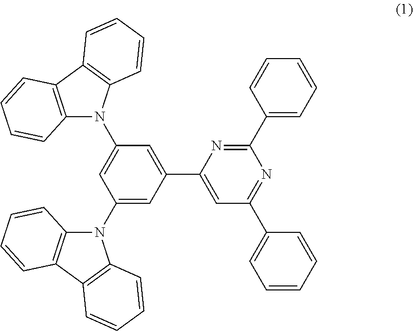

As for a complex such as BAlq represented by the following chemical formula (2), an aromatic cyclic structure and a hetero cyclic structure, which are directly bonded to metals or indirectly through an atom, are also counted as the cyclic structure. Accordingly, since BAlq has six cyclic structures, BAlq is included in the aromatic heterocyclic derivative used as the blocking layer of the invention.

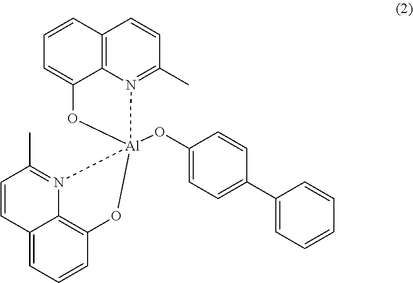

Bphen represented by the following chemical formula (3) has five cyclic structures.

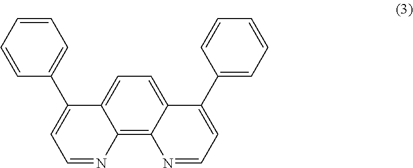

Specific examples of the aromatic heterocyclic derivative having six or more cyclic structures contained in the blocking layer are structures represented by the following general formulae (BL-1) to (BL-6). However, the aromatic heterocyclic derivative is not limited to these compounds.

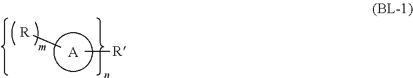

Signs in the formula (BL-1) will be described.

A represents a monocyclic heterocyclic group. R represents a group selected from a substituted or unsubstituted alkyl group, a substituted or unsubstituted aryl group, and a substituted or unsubstituted heteroaryl group, or residues of combination of two or more thereof. When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof. m is an integer of 0 to 4. n is an integer of 1 to 5. When a plurality of As and Rs are present, the plurality of As and Rs each may be the same or different. In the formula (BL-1), a total number of A, R and R′ included in a molecule is six or more, in which A, R and R′ represent a ring formed by a covalent bond of non-metal atoms.

Examples of the monocyclic heterocyclic group represented by A are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan and tetrazole. Examples of the alkyl group are preferably a methyl group, ethyl group, propyl group, isopropyl group, butyl group, sec-butyl group, tert-butyl group, isobutyl group, cyclobutyl group, cyclopentyl group and cyclohexyl group.

Examples of the aryl group are preferably a phenyl group, naphthyl group, fluorenyl group, biphenyl group, terphenyl group, phenanthryl group, fluoranthenyl group, benzofluoranthenyl group, benzanthryl group, pyrenyl group, benzphenanthryl group, benzochrysenyl group, chrysenyl group, triphenylene group and benzotrienylenyl group.

Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan and tetrazole.

The alkylene group is preferably an n-valent residue of the groups listed above as the alkyl group.

The arylene group is preferably an n-valent residue of the groups listed above as the aryl group.

The heteroarylene group is preferably an n-valent residue of the groups listed above as the heteroaryl group.

A structure represented by the general formula (BL-1) also includes the following.

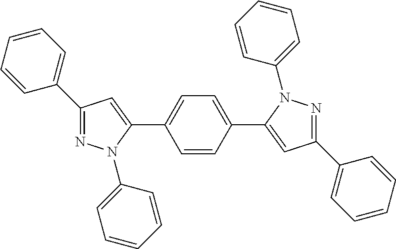

Next, structures represented by the general formula (BL-2) will be described.

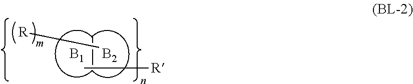

Signs in the formula (BL-2) will be described.

B₁ and B₂ both represent a cyclic structure. Adjacent Bs are fused to form a ring. At least one of B₁ and B₂ is structured to have a hetero atom. Such a fused cyclic structure formed by B₁ and B₂ is referred to as B₁-B₂ ring.

R represents a group selected from a substituted or unsubstituted alkyl group, a substituted or unsubstituted aryl group, and a substituted or unsubstituted heteroaryl group, or residues of combination of two or more thereof.

When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof, or R′ directly bonds two B₁-B₂ rings in a single bond. m is an integer of 0 to 6. n is an integer of 1 to 5.

When a plurality of B₁-B₂ rings and Rs are present, the plurality of B₁-B₂ rings and Rs each may be the same or different. In the formula (BL-2), a total number of B₁, B₂, R and R′ included in a molecule is six or more, in which B₁, B₂, R and R′ represent a ring formed by a covalent bond of non-metal atoms.

Examples of the alkyl group and the aryl group are preferably the same as those described in relation to the general formula (BL-1). Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan, tetrazole, benzimidazole, imidazopyridine, indazole, quinoline, isoquinoline, quinoxaline, naphthyridine, benzoxazole and benzthiazole.

The alkylene group, arylene group and heteroarylene group are preferably an n-valent residue of the groups listed above as the alkyl group, aryl group and heteroaryl group.

Examples of a structure of B₁-B₂ ring are preferably fused cyclic structures listed below in the general formulae (BL-2-1).

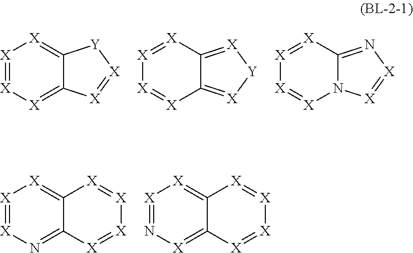

Signs in the formulae (BL-2-1) will be described.

X represents CR″ or N.

Y represents one of O, S, NR″ and C(R″)₂. At least one of Ys in a single structure is O, S or NR″.

One of R″s is used as a bonding portion to R′. The rest of R″s each are a hydrogen atom or substituents same as those of R.

C represents a carbon atom. O represents an oxygen atom. S represents a sulfur atom. N represents a nitrogen atom.

A structure represented by the general formula (BL-2) also includes the following.

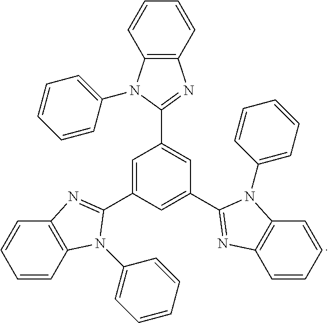

Next, structures represented by the general formula (BL-3) will be described.

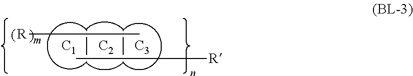

Signs in the formula (BL-3) will be described.

C₁ to C₃ each represent a cyclic structure. Adjacent Cs are fused to form a ring. At least one of C₁ to C₃ is structured to have a hetero atom. Another fused ring may be formed in such a manner as to cross-couple the adjacent Cs. Such a fused cyclic structure formed by C₁ to C₃ is referred to as C₁-C₃ ring.

R represents a group selected from a substituted or unsubstituted alkyl group, a substituted or unsubstituted aryl group, and a substituted or unsubstituted heteroaryl group, or residues of combination of two or more thereof.

When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof, or R′ directly bonds two C₁-C₃ rings in a single bond.

m is an integer of 0 to 9. n is an integer of 1 to 5. When a plurality of C₁-C₃ rings and Rs are present, the plurality of B₁-B₂ rings and Rs each may be the same or different. In the formula (BL-3), a total number of C₁ to C₃, R and R′ included in a molecule, in which C₁ to C₃, R and R′ represent a ring formed by a covalent bond of non-metal atoms.

Examples of the alkyl group and the aryl group are preferably the same as those described in relation to the general formula (BL-1). Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan, tetrazole, benzimidazole, imidazopyridine, indazole, quinoline, isoquinoline, quinoxaline, naphthyridine, benzoxazole, benzthiazole, carbazole, dibenzofuran, dibenzothiophen and phenanthroline.

The alkylene group, arylene group and heteroarylene group are preferably an n-valent residue of the groups listed above as the alkyl group, aryl group and heteroaryl group.

Examples of a structure of C₁-C₃ ring are preferably fused cyclic structures listed below in the general formulae (BL-3-1).

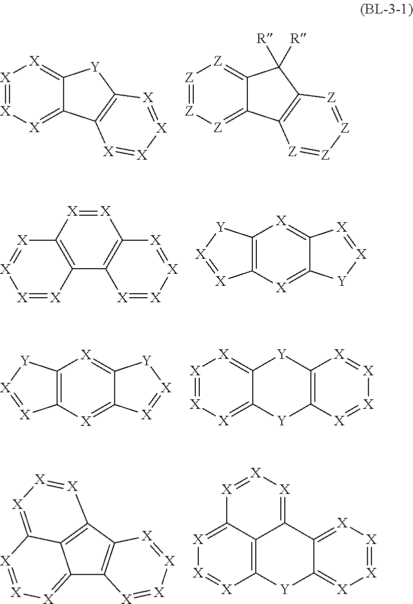

Signs in the formulae (BL-3-1) will be described.

X, Y and R″ are the same as those described in relation to the formulae (BL-2-1).

Z represents CR″ or N. At least one of Zs represents N.

A structure represented by the general formula (BL-3) also includes the following.

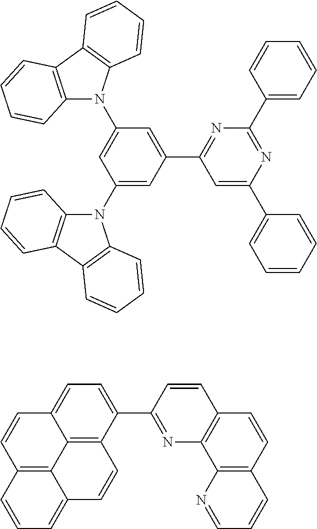

Next, structures represented by the general formula (BL-4) will be described.

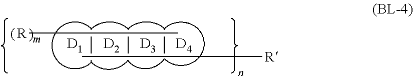

Signs in the formula (BL-4) will be described.

D₁ to D₄ each represent a cyclic structure. Adjacent Ds are fused to form a ring. At least one of D₁ to D₄ is structured to have a hetero atom. Another fused ring may be formed in such a manner as to cross-couple the adjacent Ds. Such a fused cyclic structure by D₁ to D₄ is referred to as D₁-D₄ ring.

R represents a group selected from a substituted or unsubstituted alkyl group, a substituted or unsubstituted aryl group, and a substituted or unsubstituted heteroaryl group, or residues of combination of two or more thereof.

When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof, or R′ directly bonds two D₁-D₄ rings in a single bond.

m is an integer of 0 to 11. n is an integer of 1 to 5. When a plurality of D₁-D₄ rings and Rs are present, the plurality of D₁-D₄ rings and Rs each may be the same or different. In the formula (BL-4), a total number of D₁-D₄, R and R′ included in a molecule is six or more, in which D₁-D₄, R and R′ represent a ring formed by a covalent bond of non-metal atoms.

Examples of the alkyl group and the aryl group are preferably the same as those described in relation to the general formula (BL-1). Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan, tetrazole, benzimidazole, imidazopyridine, indazole, quinoline, isoquinoline, quinoxaline, naphthyridine, benzoxazole, benzthiazole, carbazole, dibenzofuran, dibenzothiophen and phenanthroline.

The alkylene group, arylene group and heteroarylene group are preferably an n-valent residue of the groups listed above as the alkyl group, aryl group and heteroaryl group.

Examples of a structure of D₁-D₄ ring are preferably fused cyclic structures listed below in the formulae (BL-4-1).

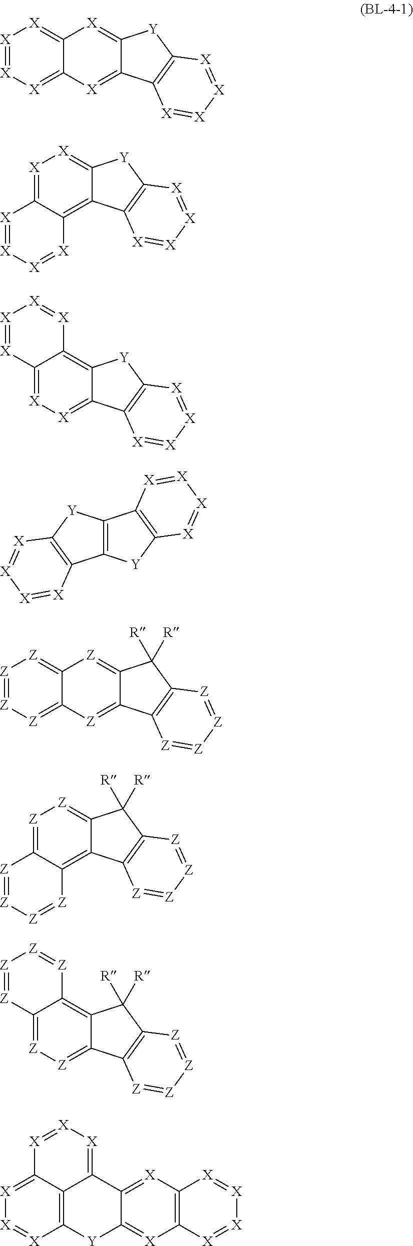

Signs in the formulae (BL-4-1) will be described.

X, Y, Z and R″ are the same as those described in relation to the formulae (BL-3-1).

A structure represented by the general formula (BL-4) also includes the following.

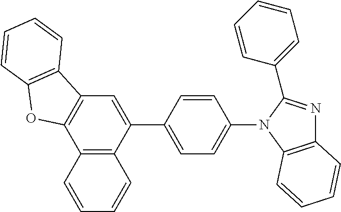

Next, structures represented by the general formula (BL-5) will be described.

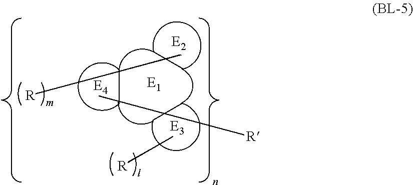

Signs in the formula (BL-5) will be described.

E₁ to E₄ each represent a cyclic structure. Adjacent Es are fused to form a ring. At least one of E₁ to E₄ is structured to have a hetero atom. Another fused ring may be formed in such a manner as to cross-couple the adjacent Es of E₁ to E₄. Such a fused cyclic structure by E₁ to E₄ is referred to as E₁-E₄ ring.

R represents a group selected from a substituted or unsubstituted alkyl group, a substituted or unsubstituted aryl group, and a substituted or unsubstituted heteroaryl group, or residues of combination of two or more thereof.

When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof, or R′ directly bonds two E₁-E₁ rings in a single bond.

(m+1) is an integer of 0 to 11. n is an integer of Ito 5. When a plurality of E₁-E₄ rings and Rs are present, the plurality of E₁-E₄ rings and Rs each may be the same or different. In the formula (BL-5), a total number of E₁-E₄, R and R′ included in a molecule is six or more, in which E₁-E₄, R and R′ represent a ring formed by a covalent bond of non-metal atoms. m and l represent the number of Rs.

Examples of the alkyl group and the aryl group are preferably the same as those described in relation to the general formula (BL-1). Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan, tetrazole, benzimidazole, imidazopyridine, indazole, quinoline, isoquinoline, quinoxaline, naphthyridine, benzoxazole, benzthiazole, carbazole, dibenzofuran, dibenzothiophen and phenanthroline.

The alkylene group, arylene group and heteroarylene group are preferably an n-valent residue of the groups listed above as the alkyl group, aryl group and heteroaryl group.

Examples of a structure of E₁-E₄ ring are preferably fused cyclic structures listed below in the formulae (BL-5-1).

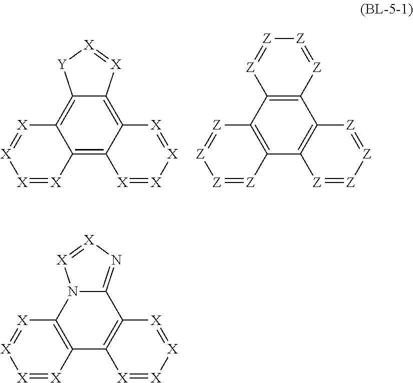

Signs in the formulae (BL-5-1) will be described.

X, Y, Z and R″ are the same as those described in relation to the formulae (BL-3-1).

Next, structures represented by the general formula (BL-6) will be described.

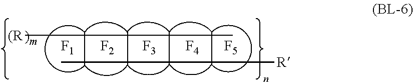

Signs in the formula (BL-6) will be described.

F₁ to F₅ each represent a cyclic structure. Adjacent Fs are fused to form a ring. At least one of F₁ to F₅ is structured to have a hetero atom. A fused ring may be formed in such a manner as to cross-couple adjacent substituents on each of Fs. Alternatively, a fused ring may be formed in such a manner as to cross-couple the adjacent Fs. Such a fused cyclic structure by F₁ to F₅ is referred to as F₁-F₅ ring.

R represents a group selected from a substituted or unsubstituted alkyl group, a substituted or unsubstituted aryl group, and a substituted or unsubstituted heteroaryl group, or residues of combination of two or more thereof.

When n is 1, R′ represents the same as R. When n is 2 to 6, R′ represents a linking group selected from a substituted or unsubstituted alkylene group, a substituted or unsubstituted arylene group, and a substituted or unsubstituted heteroarylene group, and residues of combination of two or more thereof, or R′ directly bonds two F₁-F₅ rings in a single bond.

m is an integer of 0 to 13. n is an integer of 1 to 5. When a plurality of F₁-F₅ rings and Rs are present, the plurality of F₁-F₅ rings and Rs each may be the same or different. In the formula (BL-6), a total number of F₁ to F₅, R and W included in a molecule, in which F₁ to F₅, R and R′ represent a ring formed by a covalent bond of non-metal atoms, in a molecule.

Examples of the alkyl group and the aryl group are preferably the same as those described in relation to the general formula (BL-1). Examples of the heteroaryl group are preferably pyridine, pyrimidine, pyrazine, pyridazine, triazine, tetrazine, pyrrole, imidazole, pyrazole, oxazole, isooxazole, furan, thiophene, thiazole, isothiazole, triazole, oxadiazole, thiadiazole, furazan, tetrazole, benzimidazole, imidazopyridine, indazole, quinoline, isoquinoline, quinoxaline, naphthyridine, benzoxazole, benzthiazole, carbazole, dibenzofuran, dibenzothiophen and phenanthroline.

The alkylene group, arylene group and heteroarylene group are preferably an n-valent residue of the groups listed above as the alkyl group, aryl group and heteroaryl group.

Examples of a structure of F₁-F₅ ring are preferably fused cyclic structures listed below in the general formulae (BL-6-1).

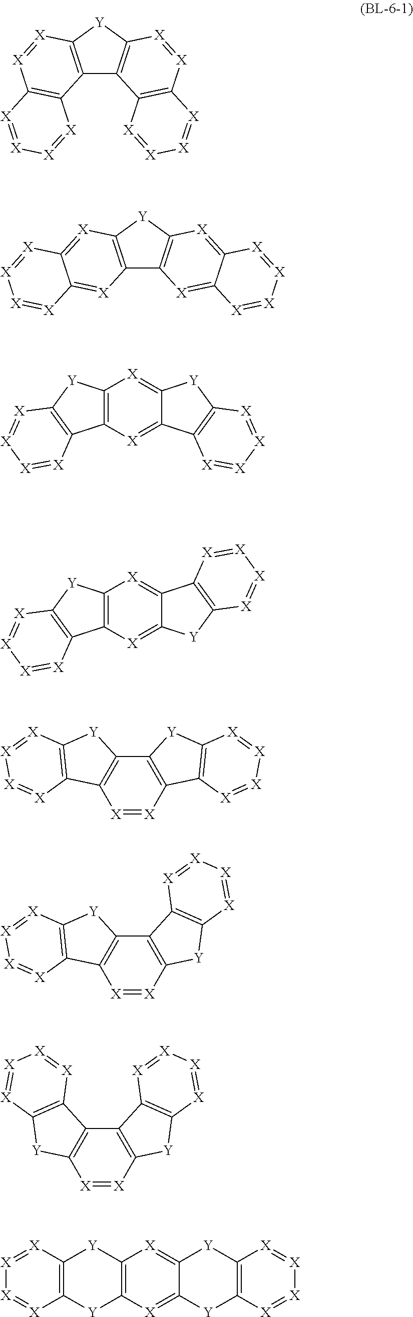

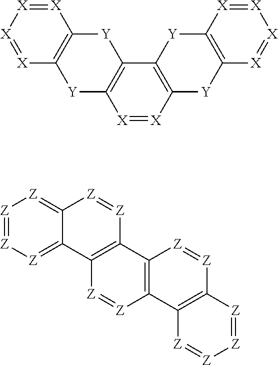

Signs in the formulae (BL-6-1) will be described.

X, Y, Z and R″ are the same as those described in relation to the formulae (BL-3-1).

A structure represented by the general formula (BL-6) also includes the following.

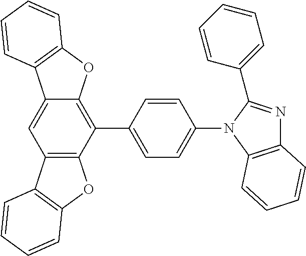

Examples of the aromatic heterocyclic derivative having six or more cyclic structures in the blocking layer are structures represented by the following general formula (BL-7). However, the aromatic heterocyclic derivative is not limited to compounds as follows.

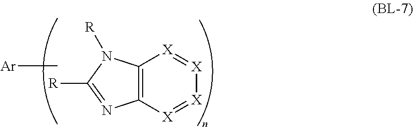

Signs in the formula (BL-7) will be described.

Ar is a substituted or unsubstituted arylene group or heteroarylene group.

X independently represents CR or N. One of Rs is bonded with Ar in a single bond. The rest of Rs are independently a hydrogen atom, fluorine atom, substituted or unsubstituted alkyl group, cycloalkyl group, aryl group, heteroaryl group, alkoxy group, aryloxy group, alkylamino group, arylamino group, alkylsilyl group, arylsilyl group, nitro group, cyano group, or a linking group formed by two or three of the aryl groups and the heteroaryl groups. n is an integer of 2 or 3.

Examples of the aryl group are preferably a phenyl group, biphenyl group, o-terphenyl group, m-terphenyl group, p-terphenyl group, naphthyl group, phenanthryl group, chrysenyl group, benzophenanthrenyl group, benzochrysenyl group, benzanthryl group, triphenyl group, fluoranthenyl group, benzofluoranthenyl group and fluorenyl group. Examples of the heteroaryl group are preferably a pyridyl group, pyrimidinyl group, pyrazinyl group, pyridazynyl group, quinolinyl group, isoquinolinyl group, quinoxalinyl group, naphthyridinyl group, imidazopyridyl group, indolyl group, indazolyl group, phenanthrolyl group, imidazolyl group, pyrazolyl group, pyrrolyl group, furanyl group, thiophenyl group, oxazolyl group, thiazolyl group, benzoxazolyl group, benzthiazolyl group, oxadiazolyl group, thiadiazolyl group, triazolyl group, tetrazolyl group, dibenzofuranyl group, dibenzothiophenyl group and carbazolyl group. The arylene group is a di- or tri-valent residue of the aryl group. The heteroarylene group is a di- or tri-valent residue of the heteroaryl group.

A structure represented by the general formula (BL-7) also includes the following.

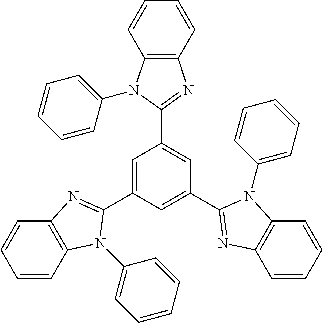

Examples of the aromatic heterocyclic derivative having six or more cyclic structures in the blocking layer are structures represented by the following general formula (BL-8). However, the aromatic heterocyclic derivative is not limited to compounds as follows.

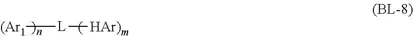

Signs in the formula (BL-8) will be described.

Ar₁ is a fused ring group in which four or more rings having one or more rings selected from a furan ring and a pyran ring are fused.

HAr is one of nitrogen-containing heterocyclic groups represented by the following formulae (BL-8-2) to (BL-8-5). n and m are each an integer of 0 to 5.

L is a single bond or an (n+m)-valent linking group formed in a single bond by two or three groups selected from a substituted or unsubstituted (n+m)-valent aryl group having 6 to 30 ring carbon atoms and a substituted or unsubstituted (n+m)-valent heterocyclic group having 5 to 30 ring atoms.

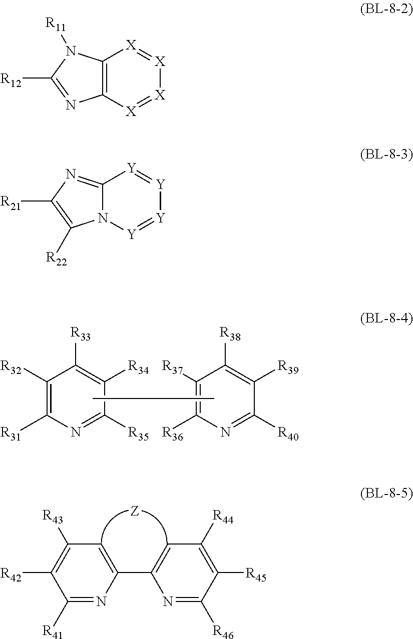

Signs in the formulae (BL-8-2) to (BL-8-5) will be described.

R₁₁, R₁₂, R₂₁, R₂₂, R₃₁ to R₄₀ and R₄₁ to R₄₆ are independently a hydrogen atom, halogen atom, substituted or unsubstituted alkyl group having 1 to 10 carbon atoms, substituted or unsubstituted cycloalkyl group having 3 to 8 ring carbon atoms, substituted silyl group having 3 to 30 carbon atoms, cyano group, substituted or unsubstituted alkoxy group having 1 to 20 carbon atoms, substituted or unsubstituted aryloxy group having 6 to 20 ring carbon atoms, substituted or unsubstituted alkylthio group having 1 to 20 carbon atoms, amino group, substituted or unsubstituted mono- or di-alkylamino group having 1 to 20 carbon atoms, substituted or unsubstituted aryl group having 6 to 30 ring carbon atoms, or substituted or unsubstituted heterocylic group having 5 to 30 ring atoms.

One of R₃₁ to R₃₅ and one of R₃₆ to R₄₀ are a single bond to bond two pyridine rings represented by the formula (BL-8-4).

X is selected from N and CR₁₃.

R₁₃ is a hydrogen atom, halogen atom, substituted or unsubstituted alkyl group having 1 to 10 carbon atoms, substituted or unsubstituted cycloalkyl group having 3 to 8 ring carbon atoms, substituted silyl group having 3 to 30 carbon atoms, cyano group, substituted or unsubstituted alkoxy group having 1 to 20 carbon atoms, substituted or unsubstituted aryloxy group having 6 to 20 ring carbon atoms, substituted or unsubstituted alkylthio group having 1 to 20 carbon atoms, amino group, substituted or unsubstituted mono- or di-alkylamino group having 1 to 20 carbon atoms, substituted or unsubstituted aryl group having 6 to 30 ring carbon atoms, or substituted or unsubstituted heterocylic group having 5 to 30 ring atoms.

When a plurality of R₁₃s are present, R₁₃s may be the same or different.

Y is selected from N and CR₂₃.

R₂₃ is a hydrogen atom, halogen atom, substituted or unsubstituted alkyl group having 1 to 10 carbon atoms, substituted or unsubstituted cycloalkyl group having 3 to 8 ring carbon atoms, substituted silyl group having 3 to 30 carbon atoms, cyano group, substituted or unsubstituted alkoxy group having 1 to 20 carbon atoms, substituted or unsubstituted aryloxy group having 6 to 20 ring carbon atoms, substituted or unsubstituted alkylthio group having 1 to 20 carbon atoms, amino group, substituted or unsubstituted mono- or di-alkylamino group having 1 to 20 carbon atoms, substituted or unsubstituted aryl group having 6 to 30 ring carbon atoms, or substituted or unsubstituted heterocylic group having 5 to 30 ring atoms.

When a plurality of R₂₃s are present, R₂₃s may be the same or different.

Z is a substituted or unsubstituted cross-linking alkylene group or alkenylene group.

One of R₁₁ to R₁₃, one of R₂₁ to R₂₃, one of R₃₁ to R₄₀ and one of R₄₁ to R₄₆ are a single bond to be bonded with L.

A preferred example of the aromatic heterocyclic derivative in the blocking layer is a compound (carbazole azine compound) represented by the following general formula (BL-9) or (BL-10).

(Cz-)ₘA (BL-9)

In the formula (BL-9), Cz is a substituted or unsubstituted carbazolyl group or a substituted or unsubstituted azacarbazolyl group. A is an aryl-substituted nitrogen-containing ring group, diaryl-substituted nitrogen-containing ring group, or triaryl-substituted nitrogen-containing ring group. m is an integer of 1 to 3.

Cz-Aₙ (BL-10)

In the formula (BL-10), Cz is a substituted or unsubstituted carbazolyl group or a substituted or unsubstituted azacarbazolyl group. A is an aryl-substituted nitrogen-containing ring group, diaryl-substituted nitrogen-containing ring group, or triaryl-substituted nitrogen-containing ring group. n is an integer of 1 to 3.

Examples of A are a substituted or unsubstituted pyridine, quinoline, pyrazine, pyrimidine, quinoxaline, triazine, imidazole, imidazopyridine, pyridazine, and benzimidazole.

A preferred example of the aromatic heterocyclic derivative in the blocking layer is a compound (ladder compound) represented by the following general formula (BL-11) or (BL-12).

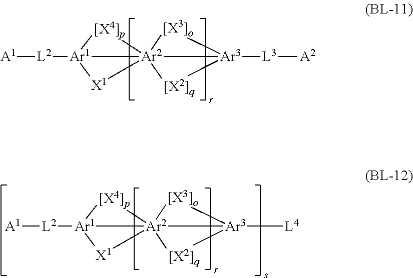

Signs in the formulae (BL-11) and (BL-11) will be described.

Ar¹, Ar² and Ar³ are independently a substituted or unsubstituted aromatic hydrocarbon group having 6 ring carbon atoms, or a substituted or unsubstituted aromatic heterocyclic group having 6 ring atoms.

Ar¹, Ar² and Ar³ may have one or more substituent Ys. A plurality of Ys may be mutually different.

Y represents an alkyl group having 1 to 20 carbon atoms, substituted or unsubstituted cycloalkyl group having 3 to 20 ring carbon atoms, alkoxy group having 1 to 20 carbon atoms, aralkyl group having 7 to 24 carbon atoms, silyl group or substituted-silyl group having 3 to 20 carbon atoms, substituted or unsubstituted aromatic hydrocarbon group or fused aromatic hydrocarbon group having 6 to 24 ring carbon atoms, or substituted or unsubstituted aromatic aromatic heterocyclic group or fused aromatic heterocyclic group having 3 to 24 ring carbon atoms.

In the formulae (BL-11) and (BL-12), X¹, X², X³ and X⁴ independently represent oxygen (O), sulfur (S), N—R1 or CR2R3.

R1, R2 and R3 independently represent an alkyl group having 1 to 20 carbon atoms, substituted or unsubstituted cycloalkyl group having 3 to 20 ring carbon atoms, aralkyl group having 7 to 24 carbon atoms, silyl group or substituted-silyl group having 3 to 20 carbon atoms, substituted or unsubstituted aromatic hydrocarbon group or fused aromatic hydrocarbon group having 6 to 24 ring carbon atoms, or substituted or unsubstituted aromatic heterocyclic group or fused aromatic heterocyclic group having 3 to 24 ring carbon atoms.

However, when: both of X¹ and X² are N—R1; o and p are 0; and q is 1, or when: both of X¹ and X³ are N—R1; p and q are 0; and o is 1, at least one R1 represents a substituted or unsubstituted monovalent fused heterocyclic group having 8 to 24 ring atoms.

In the formulae (BL-11) and (BL-12), o, p and q represent 0 or 1.

s represents 1, 2, 3 or 4, which respectively mean a monomer, dimer, trimer and tetramer, each of which uses L⁴ as a linking group.

r represents 1, 2, 3 or 4. In the formulae (BL-11) and (BL-12), L² represents a single bond, an alkylene group having 1 to 20 carbon atoms, substituted or unsubstituted cycloalkylene group having 3 to 20 ring carbon atoms, divalent silyl group or divalent substituted-silyl group having 2 to 20 carbon atoms, substituted or unsubstituted divalent aromatic hydrocarbon group or fused aromatic hydrocarbon group having 6 to 24 ring carbon atoms, or substituted or unsubstituted monovalent or divalent aromatic heterocyclic group or fused aromatic heterocyclic group having 3 to 24 ring carbon atoms.

In the formula (BL-11), L³ represents a single bond, an alkylene group having 1 to 20 carbon atoms, substituted or unsubstituted cycloalkylene group having 3 to 20 ring carbon atoms, divalent silyl group or divalent substituted-silyl group having 2 to 20 carbon atoms, substituted or unsubstituted divalent aromatic hydrocarbon group or fused aromatic hydrocarbon group having 6 to 24 ring carbon atoms, or substituted or unsubstituted divalent aromatic heterocyclic group or fused aromatic heterocyclic group having 3 to 24 ring carbon atoms.

In the formula (BL-12), when s is 2, L⁴ represents a single bond, an alkylene group having 1 to 20 carbon atoms, substituted or unsubstituted cycloalkylene group having 3 to 20 ring carbon atoms, divalent silyl group or divalent substituted-silyl group having 2 to 20 carbon atoms, substituted or unsubstituted divalent aromatic hydrocarbon group or fused aromatic hydrocarbon group having 6 to 24 ring carbon atoms, or substituted or unsubstituted divalent aromatic heterocyclic group or fused aromatic heterocyclic group having 3 to 24 ring carbon atoms.

When s is 3, L⁴ represents a trivalent saturated hydrocarbon group having 1 to 20 carbon atoms, substituted or unsubstituted trivalent saturated cyclic hydrocarbon group having 3 to 20 ring carbon atoms, trivalent silyl group or trivalent substituted-silyl group having 3 to 20 carbon atoms, substituted or unsubstituted trivalent aromatic hydrocarbon group or fused aromatic hydrocarbon group having 6 to 24 ring carbon atoms, or substituted or unsubstituted trivalent aromatic heterocyclic group or fused aromatic heterocyclic group having 3 to 24 ring carbon atoms.

When s is 4, L⁴ represents a tetravalent saturated hydrocarbon group having 1 to 20 carbon atoms, substituted or unsubstituted tetravalent saturated cyclic hydrocarbon group having 3 to 20 ring carbon atoms, silicon atom, substituted or unsubstituted tetravalent aromatic hydrocarbon group or fused aromatic hydrocarbon group having 6 to 24 ring carbon atoms, or substituted or unsubstituted tetravalent aromatic heterocyclic group or fused aromatic heterocyclic group having 3 to 24 ring carbon atoms.

In the formulae (BL-11) and (BL-12), A¹ represents a hydrogen atom, substituted or unsubstituted cycloalkyl group having 3 to 20 ring carbon atoms, silyl group or substituted-silyl group having 3 to 20 carbon atoms, substituted or unsubstituted aromatic hydrocarbon group or fused aromatic hydrocarbon group having 6 to 24 ring carbon atoms, or substituted or unsubstituted aromatic heterocyclic group or fused aromatic heterocyclic group having 3 to 24 ring carbon atoms.

In the formula (BL-11), A² represents a hydrogen atom, substituted or unsubstituted cycloalkyl group having 3 to 20 ring carbon atoms, silyl group or substituted-silyl group having 3 to 20 carbon atoms, substituted or unsubstituted aromatic hydrocarbon group or fused aromatic hydrocarbon group having 6 to 24 ring carbon atoms, or substituted or unsubstituted aromatic heterocyclic group or fused aromatic heterocyclic group having 3 to 24 ring carbon atoms.

In the invention, it is preferred that one of X¹ and X⁴ or one of X² and X³ in the formulae (BL-11) and (BL-12) is an oxygen atom and the compounds represented by the formulae (BL-11) and (BL-12) have a dibenzofuran structure in a molecule.

In the invention, it is more preferred that one of X¹ and X⁴ and one of X² and X³ in the formulae (BL-11) and (BL-12) are both an oxygen atom and the compounds represented by the formulae (BL-11) and (BL-12) have a benzofurano dibenzofuran structure.

A preferred example of the aromatic heterocyclic derivative in the blocking layer is a compound represented by the following general formula (BL-13) or (BL-14).

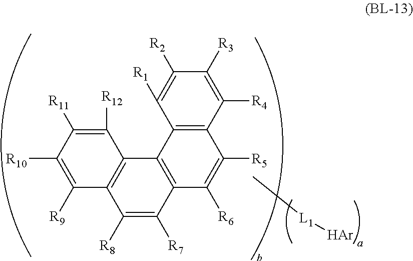

In the formula (BL-13), any group selected from R₁ to R₁₂, of which the number is represented by a, is a single bond to be bonded with L₁. The rest groups of R₁ to R₁₂, which is represented by 12-a, are each a hydrogen atom, fluorine atom, substituted or unsubstituted aryl group having 6 to 30 ring carbon atoms, or substituted or unsubstituted heterocyclic ring having 5 to 30 ring atoms.

L₁ is a single bond, substituted or unsubstituted (b+1)-valent hydrocarbon ring group having 6 to 30 ring carbon atoms, or substituted or unsubstituted (b+1)-valent heterocyclic group having 5 to 30 ring atoms.

HAr is a substituted or unsubstituted nitrogen-containing heterocyclic group.

a and b are each an integer of 1 to 4, in which at least one of a and b is 1.

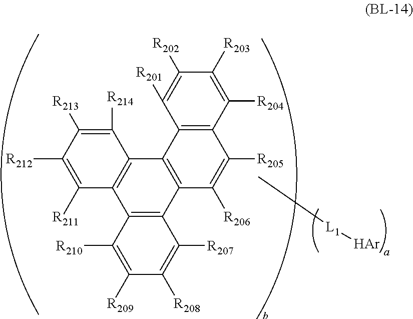

In the formula (BL-14), any group selected from R₂₀₁ to R₂₁₄, of which the number is represented by a, is a single bond to be bonded with L₁. The rest of R₂₀₁ to R₂₁₄, which is represented by 14-a, are each a hydrogen atom, fluorine atom, substituted or unsubstituted alkyl group having 1 to 10 carbon atoms, substituted or unsubstituted cycloalkyl group having 3 to 8 carbon atoms, substituted or unsubstituted alkylsilyl group having 3 to 30 carbon atoms, substituted or unsubstituted arylsilyl group having 8 to 30 ring carbon atoms, substituted or unsubstituted alkoxy group having 1 to 20 carbon atoms, substituted or unsubstituted aryloxy group having 6 to 20 ring carbon atoms, substituted or unsubstituted aryl group having 6 to 30 ring carbon atoms, or substituted or unsubstituted heterocylic group having 5 to 30 ring atoms.

L₁ is a single bond, substituted or unsubstituted (b+1)-valent hydrocarbon ring group having 6 to 30 ring carbon atoms, or substituted or unsubstituted (b+1)-valent heterocyclic group having 5 to 30 ring atoms.

HAr is a substituted or unsubstituted nitrogen-containing heterocyclic group.

a and b are each an integer of 1 to 4, in which at least one of a and b is 1.

HAr in the above formulae (BL-13) and (BL-14) is exemplified by the following formulae (BL-13-1) to (BL-13-5).

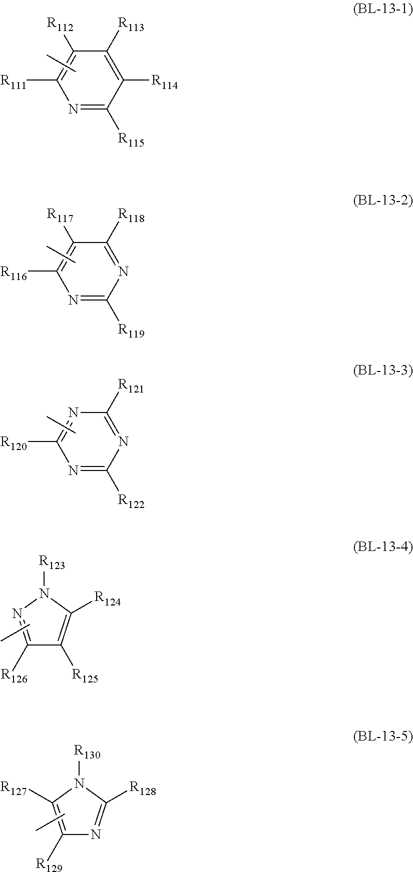

In the formulae (BL-13-1) to (BL-13-5), R₁₁₁ to R₁₃₀ are a hydrogen atom or substituent. In R₁₁₁ to R₁₃₀, adjacent substituents may be bonded with each other to form a saturated or unsaturated ring.

One of R₁₁₁ to R₁₁₅, one of R₁₁₆ to R₁₁₉, one of R₁₂₀ to R₁₂₂, one of R₁₂₃ to R₁₂₆, and one of R₁₂₇ to R₁₃₀ are each a single bond to be bonded with L₁.

As a blocking layer material, a nitrogen-containing heterocyclic derivative represented by the following formula (BL-15) is usable.

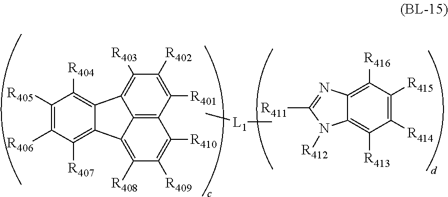

In the formula (BL-15), R₄₀₁ to R₄₁₆ are each a hydrogen atom, fluorine atom, substituted or unsubstituted alkyl group having 1 to 10 carbon atoms, substituted or unsubstituted cycloalkyl group having 3 to 10 carbon atoms, substituted or unsubstituted alkylsilyl group having 3 to 30 carbon atoms, substituted or unsubstituted arylsilyl group having 8 to 30 ring carbon atoms, substituted or unsubstituted alkoxy group having 1 to 20 carbon atoms, substituted or unsubstituted aryloxy group having 6 to 20 ring carbon atoms, substituted or unsubstituted alkylamino group, substituted or unsubstituted arylamino group, substituted or unsubstituted aryl group having 6 to 30 ring carbon atoms, or substituted or unsubstituted heterocylic group having 5 to 30 ring atoms. One of R₄₀₁ to R₄₁₀ and one of R₄₁₁ to R₄₁₆ are a single bond to be bonded with L₁. In R₄₁₁ to R₄₁₆, adjacent substituents may form a saturated or unsaturated ring.

L₁ is a single bond, substituted or unsubstituted (c+d)-valent hydrocarbon group having 6 to 30 ring carbon atoms, or substituted or unsubstituted (c+d)-valent heterocyclic group having 5 to 30 ring atoms.

c and d each represent an integer of 1 to 3.

However, L₁ and R₄₀₁ to R₄₁₆ are not an anthracene-containing group.

A preferred example of the aromatic heterocyclic derivative in the blocking layer is a compound represented by the following general formula (BL-18).

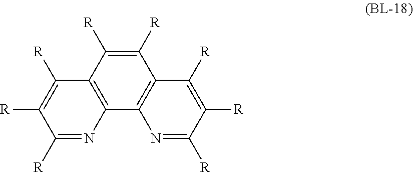

In the formula (BL-18), R independently represents a hydrogen atom, fluorine atom, substituted or unsubstituted alkyl group, cycloalkyl group, aryl group, heteroaryl group, alkoxy group, aryloxy group, alkylamino group, arylamino group, alkylsilyl group, arylsilyl group, nitro group, cyano group, or a linking group formed by two or three of the aryl groups and the heteroaryl groups.

Examples of the aryl group are preferably a phenyl group, biphenyl group, o-terphenyl group, m-terphenyl group, p-terphenyl group, naphthyl group, phenanthryl group, chrysenyl group, benzophenanthryl group, benzochrysenyl group, benzanthryl group, triphenyl group, fluoranthenyl group, benzofluoranthenyl group and fluorenyl group. Examples of the heteroaryl group are preferably a pyridyl group, pyrimidinyl group, pyrazinyl group, pyridazynyl group, quinolinyl group, isoquinolinyl group, quinoxalinyl group, naphthyridinyl group, imidazopyridyl group, indolyl group, indazolyl group, phenanthrolyl group, imidazolyl group, pyrazolyl group, pyrrolyl group, furanyl group, thiophenyl group, oxazolyl group, thiazolyl group, triazolyl group, tetrazolyl group, dibenzofuranyl group, dibenzothiophenyl group and carbazolyl group.

For instance, the following compound is listed as an example.

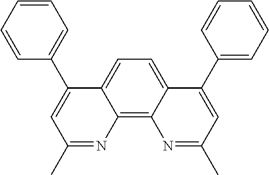

Examples of the aromatic heterocyclic derivative in the blocking layer are preferably a compound represented by the following general formula (BL-19).

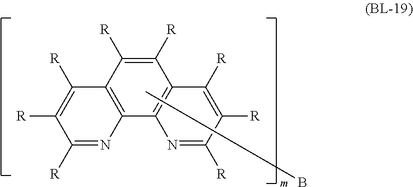

In the formula (BL-19), one of Rs is a single bond to be bonded with B. The rest of Rs independently represent a hydrogen atom, fluorine atom, substituted or unsubstituted alkyl group, cycloalkyl group, aryl group, heteroaryl group, alkoxy group, aryloxy group, alkylamino group, arylamino group, alkylsilyl group, arylsilyl group, nitro group, cyano group, or a linking group formed by two or three of the aryl groups and the heteroaryl groups. m is an integer of 2 or more. B is a single bond or a linking group. Specifically, B is a substituted or unsubstituted m-valent alkylene group, substituted or unsubstituted alkenylene group, substituted or unsubstituted m-valent arylene group, substituted or unsubstituted m-valent heteroarylene group, m-valent linking group formed by two to four aryl groups and heteroaryl groups, or m-valent group represented by the following formula (BL-20).

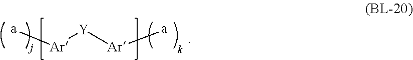

In the formula (BL-20), Ar′ is independently a substituted or unsubstituted arylene group or heteroarylene group. a represents a bonding position with a phenanthroline structure shown in the formula (BL-19). Y is O, S or CR′2. R′ is independently a substituted or unsubstituted alkyl group, substituted or unsubstituted aryl group, substituted or unsubstituted heteroaryl group. R's may be bonded to each other to form a saturated or unsaturated ring. j and k are independently an integer of 1 or more, which satisfies j+k=m.

Examples of the aryl group are preferably a phenyl group, biphenyl group, o-terphenyl group, m-terphenyl group, p-terphenyl group, naphthyl group, phenanthryl group, chrysenyl group, benzophenanthryl group, benzochrysenyl group, benzanthryl group, triphenyl group, fluoranthenyl group, benzofluoranthenyl group and fluorenyl group. Examples of the heteroaryl group are preferably a pyridyl group, pyrimidinyl group, pyrazinyl group, pyridazynyl group, quinolinyl group, isoquinolinyl group, quinoxalinyl group, naphthyridinyl group, imidazopyridyl group, indolyl group, indazolyl group, phenanthrolyl group, imidazolyl group, pyrazolyl group, pyrrolyl group, furanyl group, thiophenyl group, oxazolyl group, thiazolyl group, triazolyl group, tetrazolyl group, dibenzofuranyl group, dibenzothiophenyl group and carbazolyl group.

For instance, the following compound is listed as an example.

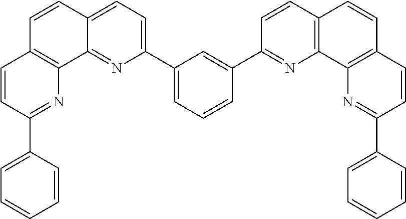

The electron injecting layer is interposed between the blocking layer and the cathode. The electron injecting layer facilitates electron injection from the cathode. Specifically, for instance, the electron injecting layer may have a stacked structure of an alkali metal compound, alkali metal or alkali metal complex on a typical electron transporting material. A material for forming the blocking layer may be doped with a donor represented by an alkali metal compound, alkali metal or alkali metal complex.

In the invention, an electron mobility of the aromatic heterocyclic derivative in the blocking layer is preferably 10⁻⁶ cm²/Vs or more in an electric field intensity of 0.04 MV/cm to 0.5 MV/cm.

This electron mobility aims for promotion of electron injection to the emitting layer and improvement in exciton density in the emitting layer to effectively cause the TTF phenomenon.

A film thickness of the blocking layer in the invention is preferably 10 nm or less. This film thickness aims for prevention of triplet exciton diffusion and reduction of suppression of electron injection to the emitting layer even at a low electron mobility of the blocking layer, thereby effectively causing the TTF phenomenon.

The electron mobility of the aromatic heterocyclic derivative in the blocking layer is effective at 1×10⁻⁸ cm²/Vs or less in an electric field intensity of 0.04 MV/cm to 0.5 MV/cm.

In the electron injecting layer of the invention, the electron mobility is preferably 1×10⁻⁶ cm²/Vs or more in an electric field intensity of 0.04 MV/cm to 0.5 MV/cm.

This electron mobility aims for promotion of electron injection to the emitting layer and improvement in exciton density in the emitting layer to effectively causes the TTF phenomenon.

Examples of the donor to be doped in the above electron injecting layer are as follows.

A donor metal refers to a metal having a work function of 3.8 eV or less. The donor metal is preferably an alkali metal, alkali earth metal and rare earth metal, more preferably Cs, Li, Na, Sr, K, Mg, Ca, Ba, Yb, Eu and Ce.

A donor metal compound is a compound including the above donor metal, preferably a compounding including the alkali metal, alkali earth metal and rare earth metal, more preferably a halogenide, oxide, carbonate and borate of these metals. Compounds represented by MOx (M: a donor metal, x: 0.5 to 1.5), MFx (x: 1 to 3) and M(CO₃)x (x: 0.5 to 1.5) are exemplified.

A donor metal complex is a complex of the above donor metal, preferably an organic metal complex of the alkali metal, alkali earth metal or rare earth metal. The organic metal complex represented by the following formula (I) is preferable.

MQ)ₙ (I)

In the formula (I), M is a donor metal; Q is a ligand, preferably a carboxylic acid derivative, diketone derivative or quinoline derivative; and n is an integer of 1 to 4.

The donor metal complex is exemplified by a tungsten waterwheel disclosed in JP-A-2005-72012. Alternatively, a phthalocyanine compound and the like with a central metal of an alkali metal or an alkali earth metal, which are disclosed in JP-A-11-345687, are usable as the donor metal complex.

One type of the above donors may be used alone or two or more types may be used in combination.

Conditions to efficiently cause the TTF phenomenon will be described in terms of a relationship between the affinity of the host and that of the dopant. Hereinafter, the affinity of the host is described as Aₕ, the affinity of the dopant as A_{d}, ionization potential of the host as Iₕ and ionization potential of the dopant as I_{d}.

Now, the conditions will be described according to the following cases.

[1] Case of Aₕ>A_{d}

[2] Case of Aₕ<A_{d}

[3] Case where Dopant Satisfying Aₕ<A_{d} and Dopant Satisfying Aₕ>A_{d} Coexist

[1] Case of Aₕ>A_{d}

A case where a relationship of Aₕ>A_{d} is satisfied will be described. The dopant used in this exemplary embodiment is a dopant emitting fluorescent light of a main peak wavelength of 550 nm or less (hereinafter occasionally referred to as a fluorescent dopant having a main peak wavelength of 550 nm or less). The dopant exhibits a relatively large energy gap. Accordingly, when the relationship of Aₕ>A_{d} is satisfied, a relationship of Iₕ>I_{d} is simultaneously satisfied. Consequently, the dopant easily functions as a hole trap.

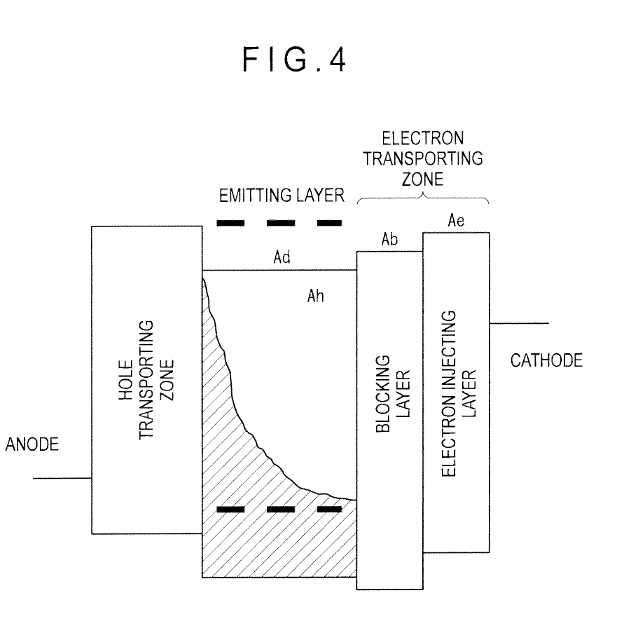

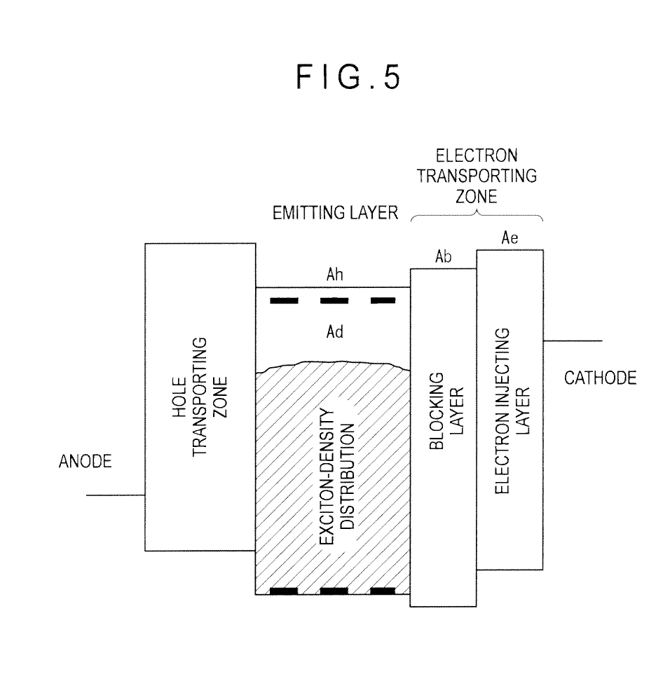

For instance, FIG. 4 shows an Ip−Af relationship of the host and the dopant in the emitting layer in the above case. In FIG. 4, a shaded area in the emitting layer shows an exciton-density distribution. The same applies to FIGS. 5 to 7. FIG. 4 shows the relationship in a case of Aₕ>A_{b}>Aₑ.

When a gap in ionization potential between the host and the dopant becomes large, the dopant is likely to have a hole-trapping property, whereby triplet excitons are generated not only on the host molecule but directly on the dopant molecule. Consequently, the triplet excitons generated directly on the dopant are increased. When a relationship of E^{T}ₕ<E^{T}_{d} is satisfied, triplet exciton energy on the dopant molecule is transferred onto the host molecule by Dexter energy transfer, resulting in that all the triplet excitons gather on the host. As a result, the TTF phenomenon occurs efficiently.

In the invention, it is preferred that the hole transporting layer is adjacent to the emitting layer in the hole transporting zone and a triplet energy E^{T}ₕₒ of the hole transporting layer is larger than a triplet energy E^{T}ₕ of the host.

When the dopant has a hole-trapping property, the holes injected from the hole transporting zone to the emitting layer are trapped by the dopant. Accordingly, recombination often occurs in the emitting layer near the anode. A typically-known hole transporting material used for the hole transporting zone often exhibits a larger triplet energy than the host. Accordingly, diffusion of the triplet excitons on holes-side has not been a problem.

However, even though recombinations often occur near the anode, the triplet exciton density in the interface of the electron transporting zone cannot be ignored. Even under such conditions, highly efficient recombinations can be achieved by increasing the triplet energy of the blocking layer.

Other factors to determine recombination areas are a carrier mobility, ionization potential, affinity and film thickness of each of the hole transporting zone and the electron transporting zone. For instance, when the film thickness of the hole transporting zone is thicker than that of the electron transporting zone, an amount of the electrons injected to the emitting layer is relatively decreased. As a result, the recombination areas are shifted near the electron transporting zone. In such a case, when the blocking layer having a large triplet energy as in the invention is used, the TTF phenomenon can be efficiently induced.

The host and the dopant that satisfy the above relationship in the affinity are selected from, for instance, the following compounds (see JP-A-2010-50227 (Japanese Patent Application No. 2008-212102) and the like).

The host is an anthracene derivative and a polycyclic aromatic skeleton-containing compound, preferably the anthracene derivative.

The dopant is at least one compound selected from the group consisting of a pyrene derivative, aminoanthracene derivative, aminochrysene derivative and aminopyrene derivative.

Examples of preferable combinations of the host and the dopant are the anthracene derivative as the host and at least one compound selected from the group consisting of a pyrene derivative, aminoanthracene derivative, aminochrysene derivative and aminopyrene derivative as the dopant.

The aminoanthracene derivative is exemplified by a compound represented by the following formula (4).

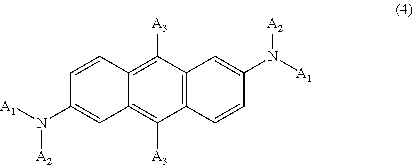

In the formula (4), A₁ and A₂ independently represent a substituted or unsubstituted aliphatic hydrocarbon group having 1 to 6 carbon atoms, substituted or unsubstituted aromatic hydrocarbon group having 6 to 20 ring carbon atoms, or substituted or unsubstituted heterocyclic aromatic hydrocarbon group having 5 to 19 ring atoms and containing nitrogen, sulfur or oxygen atom.

A₃ independently represents a substituted or unsubstituted aliphatic hydrocarbon group having 1 to 6 carbon atoms, substituted or unsubstituted aromatic hydrocarbon group having 6 to 20 ring carbon atoms, substituted or unsubstituted heterocyclic aromatic hydrocarbon group having 5 to 19 ring atoms, or a hydrogen atom. The heterocyclic aromatic hydrocarbon group includes nitrogen, sulfur or oxygen atom.

The aminochrysene derivative is exemplified by a compound represented by the following formula (5).

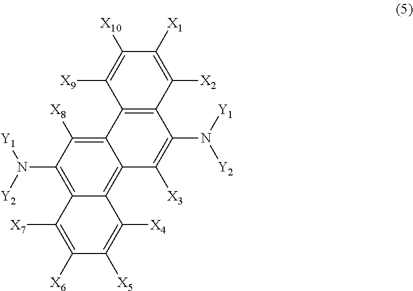

In the formula (5), X₁ to X₁₀ each represent a hydrogen atom or a substituent. Y₁ and Y₂ each represent a substituent.

X₁ to X₁₀ are preferably a hydrogen atom. Y₁ and Y₂ are preferably a substituted or unsubstituted aromatic ring having 6 to 30 ring carbon atoms. The substituent of the aromatic ring is preferably an alkyl group having 1 to 6 carbon atoms. The aromatic ring is preferably an aromatic ring having 6 to 10 ring carbon atoms or a phenyl group.

The aminopyrene derivative is exemplified by a compound represented by the following formula (6).

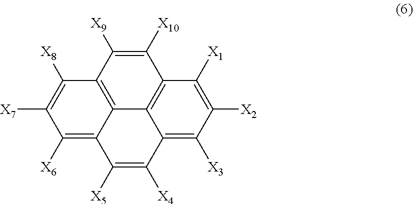

In the formula (6), X₁ to X₁₀ each represent a hydrogen atom or a substituent. X₃ and X₈ or X₂ and X₇ each represent —NY₁Y₂ (Y₁ and Y₂: substituents). When X₃ and X₈ each represent —NY₁Y₂, it is preferred that X_{2,4,5,7,9,10} represent a hydrogen atom, X₁ and X₆ represent a hydrogen atom, alkyl group or cycloalkyl group. When X₂ and X₇ each represent —NY₁Y₂, it is preferred that X_{1,3-6,8-10} are a hydrogen atom. Y₁ and Y₂ are preferably a substituted or unsubstituted aromatic ring, e.g., a phenyl group and a naphthyl group. The substituent of the aromatic ring is exemplified by an alkyl group having 1 to 6 carbon atoms.

The anthracene derivative is preferably a compound represented by the following formula (7).

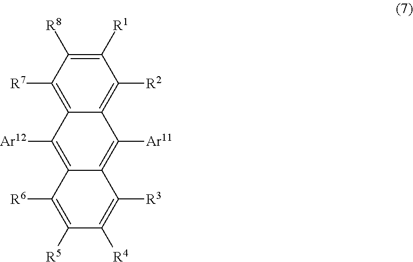

In the formula (7), Ar¹¹ and Ar¹² independently represent a substituted or unsubstituted aryl group having 6 to 50 ring carbon atoms, or a substituted or unsubstituted heterocyclic group having 5 to 50 ring atoms. R¹ to R⁸ independently represent a group selected from a hydrogen atom, a substituted or unsubstituted aryl group having 6 to 50 ring carbon atoms, or a substituted or unsubstituted heterocyclic group having 5 to 50 ring atoms, substituted or unsubstituted alkyl group having 1 to 50 carbon atoms, substituted or unsubstituted cycloalkyl group having 3 to 50 ring carbon atoms, substituted or unsubstituted alkoxy group having 1 to 50 carbon atoms, substituted or unsubstituted aralkyl group having 7 to 50 carbon atoms, substituted or unsubstituted aryloxy group having 6 to 50 ring carbon atoms, substituted or unsubstituted arylthio group having 6 to 50 ring carbon atoms, substituted or unsubstituted alkoxycarbonyl group having 2 to 50 carbon atoms, substituted or unsubstituted silyl group, carboxyl group, halogen atom, cyano group, nitro group and hydroxy group.

Among these anthracene derivatives, one of the following anthracene derivatives (A), (B) and (C) is preferably selected according to an arrangement and a desired property of an organic EL device to be applied.

### (Anthracene Derivative (A))

In the anthracene derivative, Ar¹¹ and Ar¹² of the formula (7) are independently a substituted or unsubstituted fused aryl group having 10 to 50 ring carbon atoms. The anthracene derivative can be classified into the cases: a case where the substituted or unsubstituted fused aryl groups represented by Ar¹¹ and Ar¹² are the same; and a case where the substituted or unsubstituted fused aryl groups represented by Ar¹¹ and Ar¹² are different.

Specifically, examples of the anthracene derivative are anthracene derivatives represented by the following formulae (7-1) to (7-3) and an anthracene derivative in which Ar¹¹ and Ar¹² are mutually different substituted or unsubstituted fused aryl groups.

In the anthracene derivative represented by the following formula (7-1), Ar¹¹ and Ar¹² are a substituted or unsubstituted 9-phenanthrenyl group.

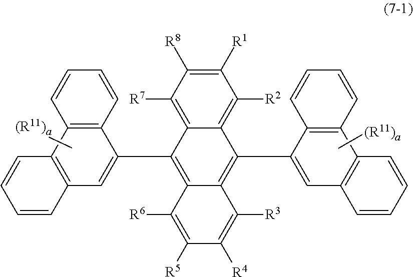

In the formula (7-1), R¹ to R⁸ represent the same as described above.

R¹¹ independently represents a group selected from a hydrogen atom, a substituted or unsubstituted aryl group having 6 to 50 ring carbon atoms, a substituted or unsubstituted heterocyclic group having 5 to 50 ring atoms, substituted or unsubstituted alkyl group having 1 to 50 carbon atoms, substituted or unsubstituted cycloalkyl group having 3 to 50 ring carbon atoms, substituted or unsubstituted alkoxy group having 1 to 50 carbon atoms, substituted or unsubstituted aralkyl group having 7 to 50 carbon atoms, substituted or unsubstituted aryloxy group having 6 to 50 ring carbon atoms, substituted or unsubstituted arylthio group having 6 to 50 ring carbon atoms, substituted or unsubstituted alkoxycarbonyl group having 2 to 50 carbon atoms, substituted or unsubstituted silyl group, carboxyl group, halogen atom, cyano group, nitro group and hydroxy group.

a is an integer of 0 to 9. When a is an integer of 2 or more, a plurality of R¹¹s may be mutually the same or different under conditions that two substituted or unsubstituted phenanthrenyl groups are the same.

In the anthracene derivative represented by the following formula (7-2), Ar¹¹ and Ar¹² of the formula (7) are a substituted or unsubstituted 2-naphthyl group.

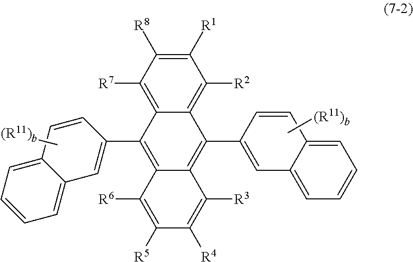

In the formula (7-2), R¹ to R⁸ and R¹¹ represent the same as described above.

b is an integer of 1 to 7. When b is an integer of 2 or more, a plurality of R¹¹s may be mutually the same or different under conditions that two substituted or unsubstituted 2-naphthyl groups are the same.

In the anthracene derivative represented by the following formula (7-3), Ar¹¹ and Ar¹² of the formula (7) are a substituted or unsubstituted 1-naphthyl group.

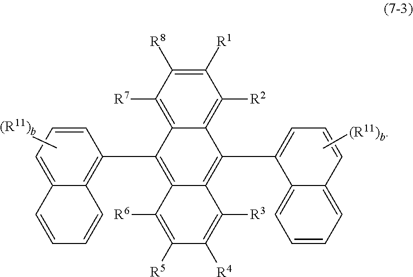

In the formula (7-3), R¹ to R⁸ and R¹¹ and b represent the same as described above. When b is an integer of 2 or more, a plurality of R¹¹s may be mutually the same or different under conditions that two substituted or unsubstituted 1-naphthyl groups are the same.

In the anthracene derivative in which Ar¹¹ and Ar¹² of the formula (7) are different substituted or unsubstituted fused aryl group, Ar¹¹ and Ar¹² are preferably one of a substituted or unsubstituted 9-phenanthrenyl group, substituted or unsubstituted 1-naphthyl group and substituted or unsubstituted 2-naphthyl group.

Specifically, it is preferable that Ar¹¹ is a 1-naphthyl group and Ar¹² is a 2-naphthyl group, that Ar¹¹ is a 1-naphthyl group and Ar¹² is a 9-phenanthrenyl group, and that Ar¹¹ is a 2-naphthyl group and Ar¹² is a 9-phenanthrenyl group.

### (Anthracene Derivative (B))

In this anthracene derivative, one of Ar¹¹ and Ar¹² of the formula (7) is a substituted or unsubstituted phenyl group and the other of Ar¹¹ and Ar¹² is a substituted or unsubstituted fused aryl group having 10 to 50 ring carbon atoms. Examples of the anthracene derivative are anthracene derivatives represented by the following formulae (7-4) to (7-5).

In the anthracene derivative represented by the following formula (7-4), Ar¹¹ of the formula (7) is a substituted or unsubstituted 1-naphthyl group and Ar¹² is a substituted or unsubstituted phenyl group.

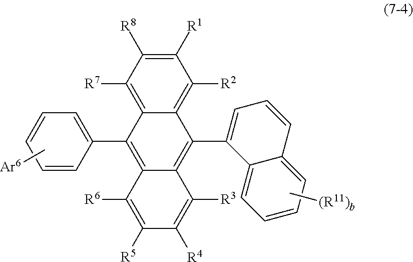

In the formula (7-4), R¹ to R⁸ and R¹¹ and b represent the same as described above.

Ar⁶ represents a substituted or unsubstituted aryl group having 6 to 50 ring carbon atoms, substituted or unsubstituted alkyl group having 1 to 50 carbon atoms, substituted or unsubstituted cycloalkyl group having 3 to 50 ring carbon atoms, substituted or unsubstituted aralkyl group having 7 to 50 carbon atoms, substituted or unsubstituted heterocyclic group having 5 to 50 ring atoms, 9,9-dimethylflorene-1-yl group, 9,9-dimethylflorene-2-yl group, 9,9-dimethylflorene-3-yl group, 9,9-dimethylflorene-4-yl group, dibenzofuran-1-yl group, dibenzofuran-2-yl group, dibenzofuran-3-yl group, or dibenzofuran-4-yl group. With a benzene ring to which Ar⁶ is bonded, Ar⁶ may form a ring such as a substituted or unsubstituted fluorenyl group and substituted or unsubstituted dibenzofuranyl group. When b is 2 or more, the plurality of R¹¹s may be mutually the same or different.

In the anthracene derivative represented by the following formula (7-5), Ar¹¹ of the formula (7) is a substituted or unsubstituted 2-naphthyl group and Ar¹² is a substituted or unsubstituted phenyl group.

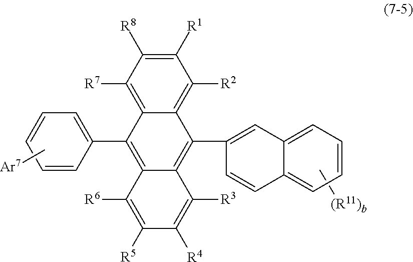

In the formula (7-5), R¹ to R⁸ and R¹¹ and b represent the same as described above. Ar⁷ represents a substituted or unsubstituted aryl group having 6 to 50 ring carbon atoms, substituted or unsubstituted heterocyclic group having 5 to 50 ring atoms, substituted or unsubstituted alkyl group having 1 to 50 carbon atoms, substituted or unsubstituted cycloalkyl group having 3 to 50 ring carbon atoms, substituted or unsubstituted aralkyl group having 7 to 50 carbon atoms, dibenzofuran-1-yl group, dibenzofuran-2-yl group, dibenzofuran-3-yl group, or dibenzofuran-4-yl group. With a benzene ring to which Ar⁷ is bonded, Ar⁷ may form a ring such as a substituted or unsubstituted fluorenyl group and substituted or unsubstituted dibenzofuranyl group. When b is 2 or more, the plurality of R¹¹s may be mutually the same or different.

### (Anthracene Derivative (C))

The anthracene derivative is represented by the following formula (7-6). Specifically, the anthracene derivative is preferably a derivative represented by one of the following formulae (7-6-1), (7-6-2) and (7-6-3).

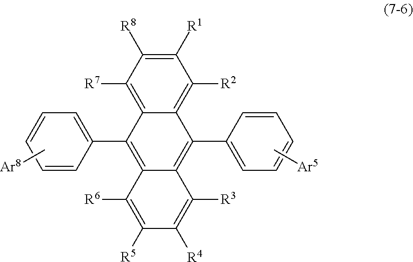

In the formula (7-6), R¹ to R⁸ and Ar⁶ represent the same as described above. Ar⁵ represents a substituted or unsubstituted aryl group having 6 to 50 ring carbon atoms, substituted or unsubstituted alkyl group having 1 to 50 carbon atoms, substituted or unsubstituted cycloalkyl group having 3 to 50 ring carbon atoms, substituted or unsubstituted aralkyl group having 7 to 50 carbon atoms, or substituted or unsubstituted heterocyclic group having 5 to 50 ring atoms. Ar⁵ and Ar⁶ are independently selected.

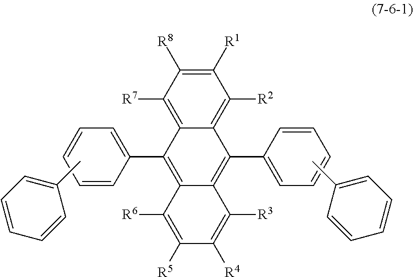

In the formula (7-6-1), R¹ to R⁸ represent the same as described above.

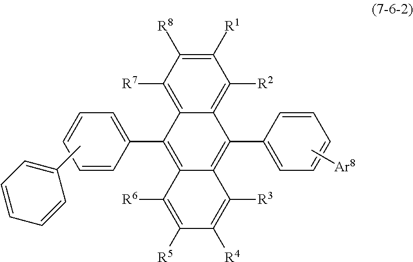

In the formula (7-6-2), R¹ to R⁸ represent the same as described above. Ar⁸ is a substituted or unsubstituted fused aryl group having 10 to 20 ring carbon atoms.

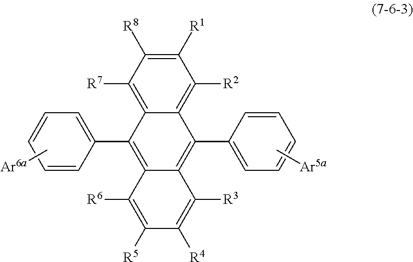

In the formula (7-6-3), R¹ to R⁸ represent the same as those of the formula (7).

Ar^{5a} and Ar^{6a} are independently a substituted or unsubstituted fused aryl group having 10 to 20 ring carbon atoms.

Examples of the substituted or unsubstituted aryl group having 6 to 50 ring carbon atoms represented by R¹ to R⁸, R¹¹, Ar⁵ to Ar⁷, Ar¹¹ and Ar¹² include a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, 6-chrysenyl group, 1-benzo[c]phenanthryl group, 2-benzo[c]phenanthryl group, 3-benzo[c]phenanthryl group, 4-benzo[c]phenanthryl group, 5-benzo[c]phenanthryl group, 6-benzo[c]phenanthryl group, 1-benzo[g]chrysenyl group, 2-benzo[g]chrysenyl group, 3-benzo[g]chrysenyl group, 4-benzo[g]chrysenyl group, 5-benzo[g]chrysenyl group, 6-benzo[g]chrysenyl group, 7-benzo[g]chrysenyl group, 8-benzo[g]chrysenyl group, 9-benzo[g]chrysenyl group, 10-benzo[g]chrysenyl group, 11-benzo[g]chrysenyl group, 12-benzo[g]chrysenyl group, 13-benzo[g]chrysenyl group, 14-benzo[g]chrysenyl group, 1-triphenyl group, 2-triphenyl group, 2-fluorenyl group, 9,9-dimethylfluorene-2-yl group, benzofluorenyl group, dibenzofluorenyl group, 2-biphenylyl group, 3-biphenylyl group, 4-biphenylyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 3-methyl-2-naphthyl group, 4-methyl-1-naphthyl group, 4-methyl-1-anthryl group, 4′-methylbiphenylyl group, and 4″-t-butyl-p-terphenyl-4-yl group. An unsubstituted phenyl group, substituted phenyl group, substituted or unsubstituted aryl group having 10 to 14 ring carbon atoms (e.g., 1-naphthyl group, 2-naphthyl group, and 9-phenanthryl group), substituted or unsubstituted fluorenyl group (2-fluorenyl group), and substituted or unsubstituted pyrenyl group (1-pyrenyl group, 2-pyrenyl group, and 4-pyrenyl group) are preferable.

Examples of the arylene group having 10 to 20 ring carbon atoms represented by Ar^{5a}, Ar^{6a} and Ar⁸ include a 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 9-naphthacenyl group, 1-pyrenyl group, 2-pyrenyl group, 4-pyrenyl group, and 2-fluorenyl group. Particularly, a 1-naphthyl group, 2-naphthyl group, 9-phenanthryl group, and fluorenyl group (2-fluorenyl group) are preferable.

Examples of the substituted or unsubstituted heterocyclic group having 5 to 50 ring atoms represented by R¹ to R⁸, R¹¹, Ar⁵ to Ar⁷, Ar¹¹ and Ar¹² include a 1-pyrrolyl group, 2-pyrrolyl group, 3-pyrrolyl group, pyrazinyl group, 2-pyrizinyl group, 3-pyrizinyl group, 4-pyrizinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, 1-phenanthridinyl group, 2-phenanthridinyl group, 3-phenanthridinyl group, 4-phenanthridinyl group, 6-phenanthridinyl group, 7-phenanthridinyl group, 8-phenanthridinyl group, 9-phenanthridinyl group, 10-phenanthridinyl group, 1-acridinyl group, 2-acridinyl group, 3-acridinyl group, 4-acridinyl group, 9-acridinyl group, 1,7-phenanthroline-2-yl group, 1,7-phenanthroline-3-yl group, 1,7-phenanthroline-4-yl group, 1,7-phenanthroline-5-yl group, 1,7-phenanthroline-6-yl group, 1,7-phenanthroline-8-yl group, 1,7-phenanthroline-9-yl group, 1,7-phenanthroline-10-yl group, 1,8-phenanthroline-2-yl group, 1,8-phenanthroline-3-yl group, 1,8-phenanthroline-4-yl group, 1,8-phenanthroline-5-yl group, 1,8-phenanthroline-6-yl group, a 1,8-phenanthroline-7-yl group, 1,8-phenanthroline-9-yl group, 1,8-phenanthroline-10-yl group, 1,9-phenanthroline-2-yl group, 1,9-phenanthroline-3-yl group, a 1,9-phenanthroline-4-yl group, 1,9-phenanthroline-5-yl group, 1,9-phenanthroline-6-yl group, 1,9-phenanthroline-7-yl group, 1,9-phenanthroline-8-yl group, 1,9-phenanthroline-10-yl group, 1,10-phenanthroline-2-yl group, 1,10-phenanthroline-3-yl group, 1,10-phenanthroline-4-yl group, 1,10-phenanthroline-5-yl group, 2,9-phenanthroline-1-yl group, 2,9-phenanthroline-3-yl group, 2,9-phenanthroline-4-yl group, 2,9-phenanthroline-5-yl group, 2,9-phenanthroline-6-yl group, a 2,9-phenanthroline-7-yl group, 2,9-phenanthroline-8-yl group, 2,9-phenanthroline-10-yl group, 2,8-phenanthroline-1-yl group, 2,8-phenanthroline-3-yl group, a 2,8-phenanthroline-4-yl group, 2,8-phenanthroline-5-yl group, 2,8-phenanthroline-6-yl group, 2,8-phenanthroline-7-yl group, 2,8-phenanthroline-9-yl group, 2,8-phenanthroline-10-yl group, 2,7-phenanthroline-1-yl group, 2,7-phenanthroline-3-yl group, 2,7-phenanthroline-4-yl group, 2,7-phenanthroline-5-yl group, 2,7-phenanthroline-6-yl group, 2,7-phenanthroline-8-yl group, 2,7-phenanthroline-9-yl group, 2,7-phenanthroline-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrol-1-yl group, 2-methylpyrrol-3-yl group, 2-methylpyrrol-4-yl group, 2-methylpyrrol-5-yl group, 3-methylpyrrol-1-yl group, 3-methylpyrrol-2-yl group, 3-methylpyrrol-4-yl group, 3-methylpyrrol-5-yl group, 2-t-butylpyrrol-4-yl group, 3-(2-phenylpropyl)pyrrol-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, and a 4-t-butyl-3-indolyl group. Among the above, a 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-carbazolyl group, 2-carbazolyl group, 3-carbazolyl group, 4-carbazolyl group, 9-carbazolyl group are preferable.

Examples of the substituted or unsubstituted alkyl group having 1 to 50 carbon atoms represented by R¹ to R⁸, R¹¹, and Ar⁵ to Ar⁷ include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, a hydroxymethyl group, a 1-hydroxyethyl group, a 2-hydroxyethyl group, a 2-hydroxyisobutyl group, a 1,2-dihydroxyethyl group, a 1,3-dihydroxyisopropyl group, a 2,3-dihydroxy-t-butyl group, a 1,2,3-trihydroxypropyl group, a chloromethyl group, a 1-chloroethyl group, a 2-chloroethyl group, a 2-chloroisobutyl group, a 1,2-dichloroethyl group, a 1,3-dichloroisopropyl group, a 2,3-dichloro-t-butyl group, a 1,2,3-trichloropropyl group, a bromomethyl group, a 1-bromoethyl group, a 2-bromoethyl group, a 2-bromoisobutyl group, a 1,2-dibromoethyl group, a 1,3-dibromoisopropyl group, a 2,3-dibromo-t-butyl group, a 1,2,3-tribromopropyl group, an iodomethyl group, a 1-iodoethyl group, a 2-iodoethyl group, a 2-iodoisobutyl group, a 1,2-diiodoethyl group, a 1,3-diiodoisopropyl group, a 2,3-diiodo-t-butyl group, a 1,2,3-triiodopropyl group, an aminomethyl group, a 1-aminoethyl group, a 2-aminoethyl group, a 2-aminoisobutyl group, a 1,2-diaminoethyl group, a 1,3-diaminoisopropyl group, a 2,3-diamino-t-butyl group, a 1,2,3-triaminopropyl group, a cyanomethyl group, a 1-cyanoethyl group, a 2-cyanoethyl group, a 2-cyanoisobutyl group, a 1,2-dicyanoethyl group, a 1,3-dicyanoisopropyl group, a 2,3-dicyano-t-butyl group, a 1,2,3-tricyanopropyl group, a nitromethyl group, a 1-nitroethyl group, a 2-nitroethyl group, a 2-nitroisobutyl group, a 1,2-dinitroethyl group, a 1,3-dinitroisopropyl group, a 2,3-dinitro-t-butyl group, and a 1,2,3-trinitropropyl group. Among the above, a methyl group, ethyl group, propyl group, isopropyl group, n-butyl group, s-butyl group, isobutyl group, and t-butyl group are preferable.

Examples of the substituted or unsubstituted cycloalkyl group having 3 to 50 ring carbon atoms represented by R¹ to R⁸, R¹¹, and Ar⁵ to Ar⁷ include a cyclopropyl group, cyclobutyl group, cyclopentyl group, cyclohexyl group, 4-methylcyclohexyl group, 1-adamantyl group, 2-adamantyl group, 1-norbornyl group, and 2-norbornyl group. Among the above, a cyclopentyl group and cyclohexyl group are preferable.

The substituted or unsubstituted alkoxy group having 1 to 50 carbon atoms represented by R¹ to R⁸ and R¹¹ is a group represented by —OY. Z is selected from the substituted or unsubstituted alkyl groups having 1 to 50 carbon atoms represented by R¹ to R⁸.

Examples of the substituted or unsubstituted aralkyl group having 7 to 50 carbon atoms represented by R¹ to R⁸, R¹¹ and Ar⁵ to Ar⁷ (in which an aryl portion has 6 to 49 carbon atoms and an alkyl portion has 1 to 44 carbon atoms) include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, 2-β-naphthylisopropyl group, 1-pyrrolylmethyl group, 2-(1-pyrrolyl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, and 1-chloro-2-phenylisopropyl group.

The substituted or unsubstituted aryloxy group having 6 to 50 carbon atoms and the substituted or unsubstituted arylthio group having 6 to 50 carbon atoms represented by R¹ to R⁸ and R¹¹ are respectively represented by —OY and SY. Y is selected from the substituted or unsubstituted aryl groups having 6 to 50 ring carbon atoms represented by R¹ to R⁸.

The substituted or unsubstituted alkoxycarbonyl groups having 2 to 50 carbon atoms represented by R¹ to R⁸ and R¹¹ (in which each of alkyl portions has 1 to 49 carbon atoms) is represented by —COOZ. Z is selected from the substituted or unsubstituted alkyl groups having 1 to 50 carbon atoms represented by R¹ to R⁸.

Examples of the substituted silyl group represented by R¹ to R⁸ and R¹¹ include a trimethylsilyl group, triethylsilyl group, t-butyldimethylsilyl group, vinyldimethylsilyl group, propyldimethylsilyl group, and triphenylsilyl group.

Examples of the halogen atom represented by R¹ to R⁸ and R¹¹ include fluorine, chlorine, bromine and iodine.

[2] Case of Aₕ<A_{d}

Using the combination of the host and the dopant which allows Aₕ<A_{d}, the advantageous effects of the blocking layer provided within the electron transporting zone is exhibited outstandingly, whereby improvement in efficiency due to the TTF phenomenon can be attained. Description will be given in the following cases of [2-1] and [2-2]. In general, an organic material has a broadening of a LUMO level in a range larger than the measured affinity level by approximately 0.2 eV.

[2-1] Difference Between A_{d} and Aₕ is Smaller than 0.2 eV

FIG. 5 shows one example of an energy band diagram in this case. Dotted lines in the emitting layer show an energy level of the dopant. As shown in FIG. 5, when a difference between A_{d} and Aₕ is smaller than 0.2 eV, the LUMO level of the dopant is included in the range of the broadening of the LUMO level of the host, so that the electrons carried within the emitting layer is unlikely to be trapped by the dopant. In other words, the dopant is unlikely to exhibit an electron-trapping property. Moreover, the dopant of the invention is a wide-gap fluorescent dopant having a main peak wavelength of 550 nm or less. When the relationship of Aₕ<A_{d} is satisfied, since the difference between Aₕ and A_{d} is approximately 0.2 eV, a difference between the ionization potential of the host and the ionization potential of the dopant is reduced. As a result, the dopant does not tend to exhibit a outstanding hole-trapping property. FIG. 5 shows the relationship in the case of Aₕ>A_{b}>Aₑ.

In other words, the dopant in this case does not tend to exhibit an outstanding trapping property for both electrons and holes. In this case, as shown by the shaded area of the emitting layer in FIG. 5, the electron-hole recombinations occur mainly on the host molecule in the broad whole area in the emitting layer, thereby generating 25% of singlet excitons and 75% of triplet excitons mainly on the host molecule. Energy of the singlet excitons generated on the host is transferred to the dopant by Forster energy transfer to contribute to a fluorescent emission of the dopant molecule. On the other hand, the transfer direction of the energy of triplet excitons depends on the triplet energy relationship of the host and the dopant. When the relationship is E^{T}ₕ>E^{T}_{d}, the triplet excitons generated on the host are transferred to a dopant which exists in the vicinity by the Dexter energy transfer. A concentration of the dopant in the emitting layer of a fluorescent device is typically as low as at a few mass % to approximately 20 mass %. Accordingly, triplet excitons which have transferred to the dopant collide with one another less frequently, resulting in a less possibility of occurrence of the TTF phenomenon. However, when the relationship of E^{T}ₕ<E^{T}_{d} is satisfied as in this exemplary embodiment, since the triplet excitons are present on the host molecule, the frequency of collision is increased, so that the TTF phenomenon easily and efficiently occur.

In the invention, the blocking layer is adjacent to the emitting layer. Since the triplet energy E^{T}ₕ of the blocking layer is set to be larger than the triplet energy E^{T}ₕ of the host, the triplet excitons are prevented from dispersing into the electron transporting zone, so that the TTF phenomenon can occur efficiently in the emitting layer.

[2-2] Difference Between A_{d} and Aₕ is Larger than 0.2 eV

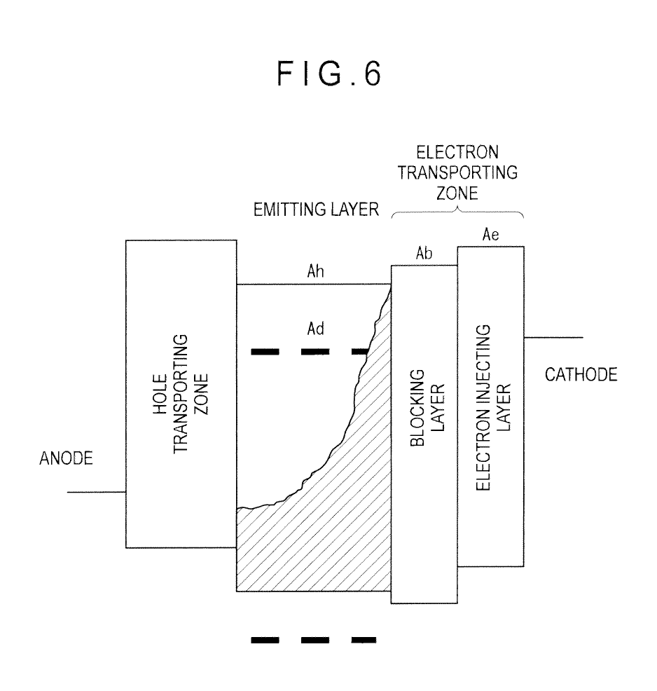

FIG. 6 shows one example of an energy band diagram in this case. The difference in affinity between the dopant and the host is increased, so that a LUMO level of the dopant is present at a position further higher than the LUMO level broadening of the host. Accordingly, the dopant is more likely to exhibit a significant electron-trapping property. Electrons trapped by the dopant are recombined with holes after the holes are transferred from the host to the dopant. In other words, unlike the condition shown in FIG. 5, the electrons and the holes are recombined in a pair not only on the host molecule but also on the dopant molecule. As a result, triplet excitons are generated not only on the host molecule but also directly on the dopant molecule. Under such conditions, when the relationship of E^{T}ₕ<E^{T}_{d} is satisfied as in this exemplary embodiment, the triplet excitons generated directly on the dopant also gather on the host by Dexter energy transfer, so that the TTF phenomenon occurs efficiently.

When the affinities satisfy the above-mentioned relationship, the possibility of trapping of electrons by the dopant is increased in the vicinity of the interface between the emitting layer and the blocking layer. As a result, recombinations occur frequently in the vicinity of the interface between the emitting layer and the blocking layer. In this case, the efficiency of confining triplet excitons by the blocking layer is increased as compared with the case mentioned in [2-1], resulting in an increase in density of triplet excitons at the interface between the emitting layer and the blocking layer. FIG. 6 shows the relationship in the case of Aₕ>A_{b}>Aₑ.

The host and the dopant that satisfy the above relationship in the Aₕ<A_{d} can be selected from, for instance, the following compounds (see JP-A-2010-50227 (Japanese Patent Application No. 2008-212102) and the like).

Examples of the host are an anthracene derivative and a polycyclic aromatic skeleton-containing compound, preferably an anthracene derivative.

Examples of the dopant are a fluoranthene derivative, pyrene derivative, arylacetylene derivative, fluoren derivative, boron complex, perylene derivative, oxadiazole derivative and anthracene derivatives, preferably fluoranthene derivative, pyrene derivative, and boron complex, more preferably fluoranthene derivative and boron complex. As for the combination of a host and a dopant, it is preferred that the host is an anthracene derivative and the dopant is a fluoranthene derivative or a boron complex.

The fluoranthene derivative is exemplified by the following compound.

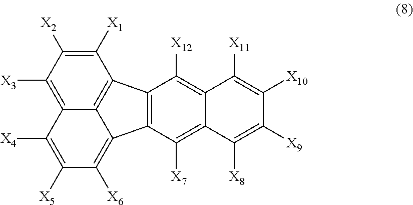

In the formula (8), X₁ to X₁₂ each represent a hydrogen atom or a substituent. Preferably, in the compound, X₁ to X₂, X₄ to X₆ and X₈ to X₁₁ are a hydrogen atom, and X₃, X₇ and X₁₂ are a substituted or unsubstituted aryl group having 5 to 50 ring atoms. Preferably, in the compound, X₁ to X₂, X₄ to X₆ and X₈ to X₁₁ are a hydrogen atom, X₃, X₇ and X₁₂ are a substituted or unsubstituted aryl group having 5 to 50 ring atoms. X₃ is —Ar₁—Ar₂, in which Ar₁ is a substituted or unsubstituted arylene group having 5 to 50 ring atoms, and Ar₂ is a substituted or unsubstituted aryl group having 5 to 50 ring atoms.

More preferably, in the compound, X₁ to X₂, X₄ to X₆ and X₈ to X₁₁ are a hydrogen atom and X₇ and X₁₂ are a substituted or unsubstituted aryl group having 5 to 50 ring atoms. X₃ is —Ar₁—Ar₂—Ar₃, in which Arᵢ and Arₐ are each a substituted or unsubstituted arylene group having 5 to 50 ring atoms, and Ar₂ is a substituted or unsubstituted aryl group having 5 to 50 ring atoms.

The boron complex is exemplified by the following compound.

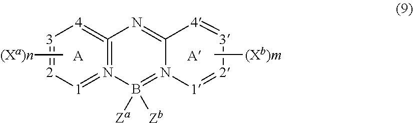

In the formula (9), A and A′ represent an independent azine ring system corresponding to a six-membered aromatic ring containing one or more nitrogen. X^{a} and X^{b} represent independently-selected substituents, which are bonded together to form a fused ring for the ring A or the ring A′. The fused ring contains an aryl or heteroaryl substituent. m and n independently represent 0 to 4. Z^{a} and Z^{b} each represent an independently-selected halide. 1, 2, 3, 4, 1′, 2′, 3′ and 4′ each represent an independently-selected carbon atom or nitrogen atom.

Desirably, the azine ring is preferably a quinolinyl ring or isoquinolinyl ring in which all of 1, 2, 3, 4, 1′, 2′, 3′ and 4′ are carbon atoms, m and n each are 2 or more, and X^{a} and X^{b} are a substituent having 2 or more carbon atoms that combine with each other to form an aromatic ring. Z^{a} and Z^{b} are desirably fluorine atoms.

The anthracene derivatives as the host in the case of [2] are the same as those described in the above “[1] Case of Aₕ>A_{d}.”

[3] In The Case Where a Dopant Satisfying Aₙ<A_{d} and a Dopant Satisfying Aₕ>A_{d} Coexist

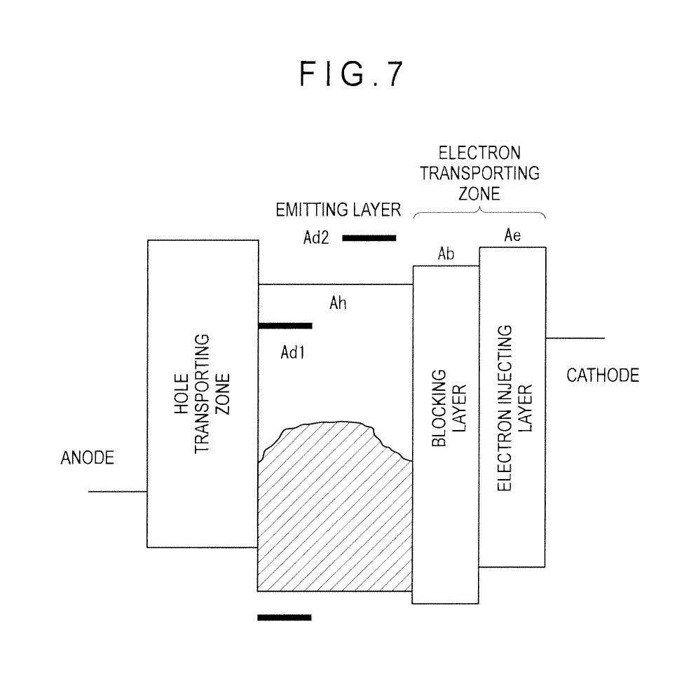

FIG. 7 shows one example of an energy band diagram when a dopant satisfying Aₕ<A_{d} and a dopant satisfying Aₕ>A_{d} are both contained in the emitting layer. In such a case, both electrons and holes are trapped properly, whereby recombination occurs in the entire region of the emitting layer. Accordingly, recombination occurs frequently also on the cathode side. By providing a blocking layer that has a large triplet energy, the TTF phenomenon occurs efficiently. FIG. 7 shows the relationship in the case of Aₕ>A_{b}>Aₑ.

In the invention, the density of excitons is large in the interface between the emitting layer and the blocking layer. In this case, holes which do not contribute to recombination in the emitting layer are injected in the blocking layer with a high probability. Accordingly, as the material to be used, in the blocking layer, among the above-mentioned aromatic heterocyclic derivatives, one having an excellent oxidation resistance is preferable

The blocking layer material desirably exhibits a reversible oxidation process in a cyclic voltammetry measurement.

Next, the measurement of the mobility by the impedance spectroscopy will be described below. The blocking layer material having a thickness of approximately 100 nm to 200 nm is preferably held between the anode and the cathode. While applying a bias DC voltage, a small alternate voltage of 100 mV or less is applied. The value of an alternate current (the absolute value and the phase) which flows at this time is measured. This measurement is performed while changing the frequency of the alternate voltage, and complex impedance (Z) is calculated from a current value and a voltage value. A frequency dependency of the imaginary part (1 mM) of the modulus M=iωZ (i: imaginary unit ω: angular frequency) is obtained. The inverse of a frequency ω at which the 1 mM becomes the maximum is defined as a response time of electrons carried in the blocking layer. The electron mobility is calculated according to the following formula.

Electron mobility=(film thickness of the blocking layer material)²/(response time·voltage)

The emitting layer may contain two or more fluorescent dopants of which the main peak wavelength is 550 nm or less. When the emitting layer contains two or more fluorescent dopants, the affinity A_{d} of at least one dopant is equal to or larger than the affinity Aₕ of the host, and the triplet energy E^{T}_{d} of this dopant is larger than the triplet energy E^{T}ₕ of the host. For instance, the affinity A_{d} of at least one dopant of the rest of the dopants may be smaller than the affinity Aₕ of the host. Containing such two kinds of dopants means containing both of a dopant satisfying Aₕ<A_{d} and a dopant satisfying Aₕ>A_{d} as described above. Efficiency can be significantly improved by providing the blocking layer having a large triplet energy.

Examples of the dopant having the affinity A_{d} that is smaller than the affinity Aₕ of the host are a pyrene derivative, aminoanthracene derivative, aminochrysene derivative, and aminopyrene derivative.

In addition to the above-mentioned hosts, dibenzofuran compounds disclosed in WO05/113531 and JP2005-314239, fluorene compounds disclosed in WO02/14244, and benzanthracene compounds disclosed in WO08/145,239 can be used.

In addition to the above-mentioned dopants, pyrene compounds disclosed in JP2004-204238, WO05/108348, WO04/83162, WO09/84512, KR10-2008-79956, KR10-2007-115588 and KR10-2010-24894, chrysene compounds disclosed in WO04/44088, and anthracene compounds disclosed in WO07/21117 can be used.

Preferably, the host and the dopant are each a compound formed by bonding of ring structures or single atoms (including bonding of a ring structure and a single atom), in which the bonding is a single bond. A compound having a carbon-carbon double bond in the part other than the ring structure thereof, is not preferable The reason thereof is that the triplet energies generated on the host and the dopant are used for the structural change of the double bond, without being used for a TTF phenomenon.

### Second Exemplary Embodiment

An organic EL device according to a second exemplary embodiment will be described below.

The organic EL device according to the second exemplary embodiment has a blocking layer different from that of the organic EL device according to the first exemplary embodiment. Specifically, whereas the aromatic heterocyclic derivative contained in the blocking layer of the organic EL device according to the first exemplary embodiment has the relationship of affinity represented by the formula (1) in relation to the host of the emitting layer, the blocking layer of the organic EL device according to the second exemplary embodiment contains an aromatic heterocyclic derivative having an azine ring and does not necessarily require to satisfy the relationship of the formula (1). In this point, the organic EL devices according to the first and second exemplary embodiments are different. As for other points, the organic EL device according to the second exemplary embodiment is the same as the organic EL device according to the first exemplary embodiment

A preferable example of the aromatic heterocyclic derivative that is contained in the blocking layer and has an azine ring is a compound represented by the following general formula (BL-21).

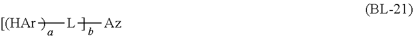

In the general formula (BL-21), HAr represents a substituted or unsubstituted heterocyclic group having 5 to 30 ring atoms. When a plurality of HAr are present, the plurality of HAr may be mutually the same or different. Az represents a substituted or unsubstituted pyrimidine, substituted or unsubstituted pyrazine, substituted or unsubstituted pyridazine, or substituted or unsubstituted triazine. L represents a single bond, a divalent to tetravalent residue of a substituted or unsubstituted aromatic hydrocarbon ring having 6 to 30 ring carbon atoms, a divalent to tetravalent residue of a substituted or unsubstituted heterocyclic ring having 5 to 30 ring atoms, or a divalent to tetravalent residue of a group in which two or three rings selected from the aromatic hydrocarbon ring and the heterocyclic ring are combined in a single bond. a is an integer of 1 to 3. b is an integer of 1 to 3.

Az preferably has a structure represented by the following formula (BL-21-1).

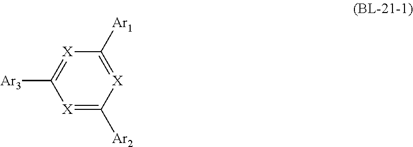

In the formula (BL-21-1), X is N or C(Ar), in which two or more X are N. Ar is selected from a hydrogen atom, substituted or unsubstituted alkyl group having 1 to 20 carbon atoms, substituted or unsubstituted aryl group having 6 to 30 ring carbon atoms, and substituted or unsubstituted heterocyclic group having 5 to 30 ring atoms. Ar₁, Ar₂ and Ar₃ are independently selected from a single bond that combines with L in the general formula (BL-21), hydrogen atom, substituted or unsubstituted alkyl group having 1 to 20 carbon atoms, substituted or unsubstituted aryl group having 6 to 30 ring carbon atoms, and substituted or unsubstituted heterocyclic group having 5 to 30 ring atoms.

HAr is preferably a substituted or unsubstituted pyridyl group, substituted or unsubstituted pyrimidinyl group, substituted or unsubstituted pyrazinyl group, substituted or unsubstituted pyridazinyl group, substituted or unsubstituted triazinyl group, substituted or unsubstituted quinolinyl group, substituted or unsubstituted isoquinolinyl group, substituted or unsubstituted quinoxalinyl group, or heterocyclic groups listed in the formulae (BL-21-2).

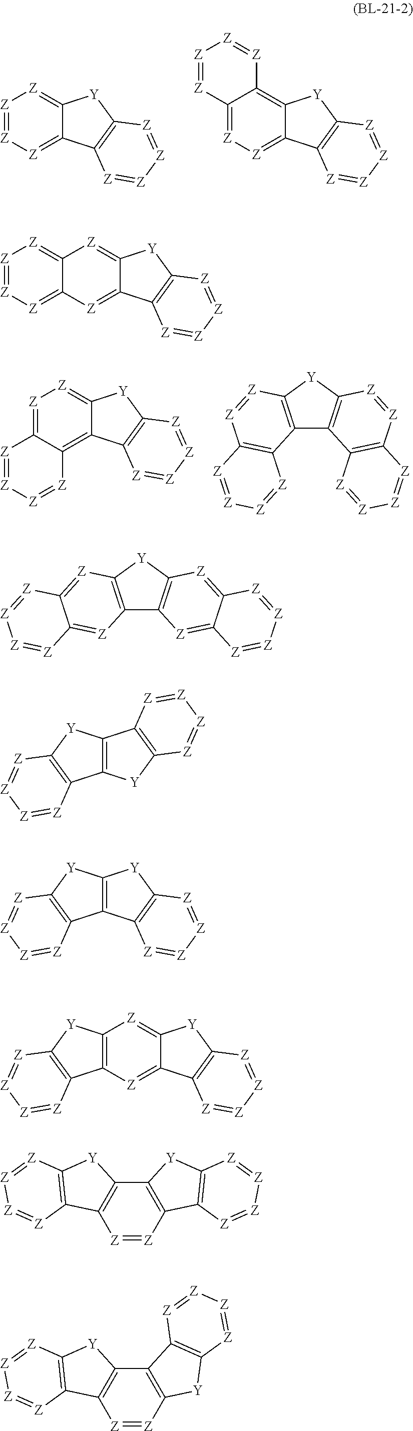

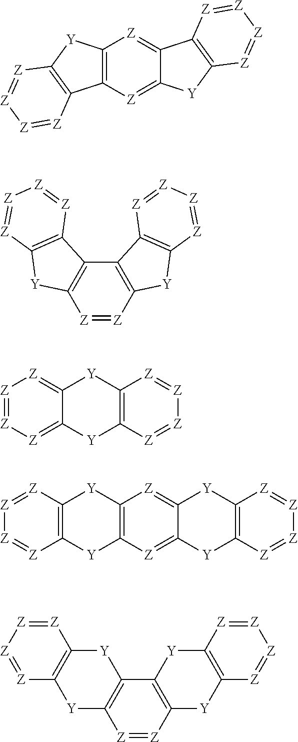

In the formulae (BL-21-2), Y is O, N(R′) or C(R′)(R′). Z is N or C(R′). At least one of Y and Z has O or N. In each heterocyclic ring, one of R′ is used as a bonding position with L and the rest of R′ are independently a hydrogen atom, halogen atom, substituted or unsubstituted alkyl group having 1 to 10 carbon atoms, substituted or unsubstituted cycloalkyl group having 3 to 8 ring carbon atoms, substituted silyl group having 3 to 30 carbon atoms, cyano group, substituted or unsubstituted alkoxy group having 1 to 20 carbon atoms, substituted or unsubstituted aryloxy group having 6 to 20 ring carbon atoms, substituted or unsubstituted aryl group having 6 to 30 ring carbon atoms, or substituted or unsubstituted heterocylic group having 5 to 30 ring atoms.

HAr is more preferably one represented by the formula (BL-21-2) in which Z is C(R′), particularly preferably a substituted or unsubstituted carbazolyl group.

a is preferably an integer of 1 or 2. b is preferably an integer of 1 or 2.

Examples of the aryl group are preferably a phenyl group, biphenyl group, o-terphenyl group, m-terphenyl group, p-terphenyl group, naphthyl group, phenanthryl group, chrysenyl group, benzophenanthrenyl group, benzochrysenyl group, benzanthryl group, triphenyl group, fluoranthenyl group, benzofluoranthenyl group and fluorenyl group, more preferably phenyl group, biphenyl group, naphthyl group, phenanthryl group.

Examples of the heterocyclic group other than HAr are preferably a pyrizinyl group, pyrazinyl group, pyrimidinyl group, pyridazinyl group, triazinyl group, indolyl group, quinolinyl group, acridinyl group, pyrrolidinyl group, dioxanyl group, piperidinyl group, monopholyl group, piperazinyl group, carbazolyl group, furanyl group, thiophenyl group, oxazolyl group, oxadiazolyl group, benzooxazolyl group, thiazolyl group, thiadiazolyl group, benzothizolyl group, triazolyl group, imidazolyl group, benzoimidazolyl group, imidazopyridyl group, benzofuranyl group and dibenzofuranyl group.

In the invention, even when the affinity A_{b} of the blocking layer and the affinity Aₑ of the electron injecting layer do not satisfy the formula (1), by providing the aromatic heterocyclic derivative having the azine ring in the blocking layer, luminous efficiency is improved. The aromatic heterocyclic derivative having the azine ring is selected from the above-mentioned aromatic heterocyclic derivatives.

### Third Exemplary Embodiment

The device of the invention may have a tandem device configuration in which at least two organic layer units including emitting layers are provided. An intermediate layer (intermediate conductive layer, charge generation layer or CGL) is interposed between the two emitting layers. An electron transporting zone can be provided in each unit. At least one emitting layer is a fluorescent emitting layer and the unit including the emitting layer satisfies the above-mentioned requirements. Specific examples of stack order are given below. The following emitting layer may be a multilayer stack of emitting layers or one organic layer unit including a charge blocking layer according to a later-described third exemplary embodiment.

anode/fluoresecent emitting layer/intermediate layer/fluoresecent emitting layer/blocking layer/electron injecting layer/cathode.

anode/fluoresecent emitting layer/blocking layer/electron injecting layer/intermediate layer/fluoresecent emitting layer/cathode.

anode/fluoresecent emitting layer/blocking layer/electron injecting layer/intermediate layer/fluoresecent emitting layer/blocking layer/cathode.

anode/fluoresecent emitting layer/blocking layer/intermediate layer/fluoresecent emitting layer/blocking layer/electron injecting layer/cathode.

anode/phosphorescent emitting layer/intermediate layer/fluoresecent emitting layer/blocking layer/electron injecting layer/cathode.

anode/fluoresecent emitting layer/blocking layer/electron injecting layer/intermediate layer/phosphorescent emitting layer/cathode.

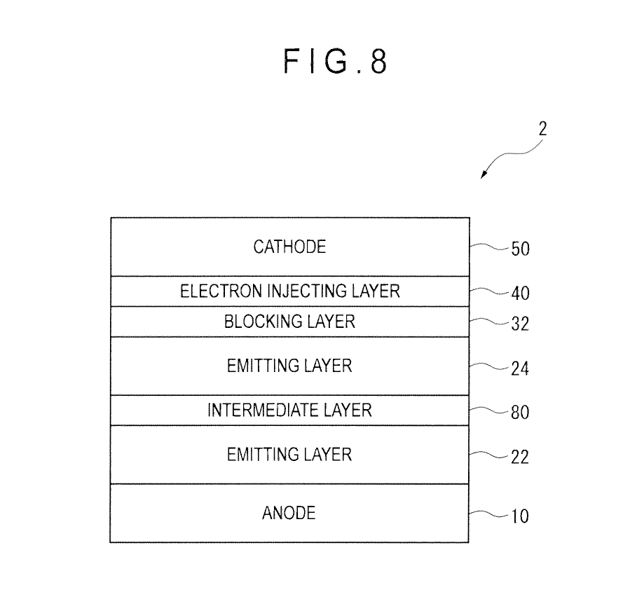

FIG. 8 shows one example of an organic EL device according to the third exemplary embodiment. An organic EL device 2 includes an anode 10, emitting layers 22 and 24 and a cathode 50 in sequential order. An intermediate layer 80 is interposed between the emitting layers 22 and 24. A blocking layer 32 is adjacent to the emitting layer 24. The electron injecting layer 80 is interposed between the blocking layer 32 and the cathode 50. The blocking layer 32, the electron injecting layer 80 and the emitting layer 24 are respectively a blocking layer, an electron injecting layer and a fluorescent emitting layer which satisfy the requirements of the invention. The other emitting layer may be either a fluorescent emitting layer or a phosphorescent emitting layer. Another blocking layer and another electron injecting layer are provided adjacent to the emitting layer 22 in sequential order. These blocking layer and electron injecting layer and the emitting layer 22 may be respectively used as the blocking layer, the electron injecting layer, and the fluorescent emitting layer which satisfy the requirements of the invention.

At least one of an electron transporting zone and hole transporting zone may be interposed between the two emitting layers 22 and 24. Three or more emitting layers may be provided, and two or more intermediate layers may be provided. When three or more emitting layers are present, an intermediate layer may or may not be present between all of the emitting layers.

The intermediate layer is a layer including at least one of the intermediate conductive layer and the charge generation layer, or at least one of the intermediate conductive layer and the charge, generation layer. The intermediate layer serves as a source for supplying electrons or holes to be injected in an emitting unit. In addition to charges injected from a pair of electrodes, charges supplied from the intermediate layer are injected into the emitting unit. Accordingly, by providing the intermediate layer, luminous efficiency (current efficiency) relative to injected current is improved.

Examples of the intermediate layer include a metal, metal oxide, mixture of metal oxides, composite oxide, and electron-accepting organic compound. Examples of the metal are preferably Mg, Al, and a film formed by co-evaporating Mg and Al. Examples of the metal oxide include ZnO, WO₃, MoO₃ and MoO₂. Examples of the mixture of the metal oxides include ITO, IZO, and ZnO:Al. Examples of the electron-accepting organic compound include an organic compound having a CN group as a substituent. The organic compound having a CN group is preferably a triphenylene derivative, tetracyanoquinodimethane derivative and indenofluorene derivative. The triphenylene derivative is preferably hexacyanohexaazatriphenylene. The tetracyanoquinodimethane derivative is preferably tetrafluoroquinodimethane and dicyanoquinodimethane. The indenofluorene derivative is preferably a compound disclsed in WO2009/011327, WO2009/069717, or WO2010/064655. The electron accepting substance may be a single substance, or a mixture with other organic compounds.

In order to easily accept the electrons from the charge generation layer, it is suitable to dope a donor represented by an alkali metal in the vicinity of an interface of the charge generation layer in the electron transporting layer. As the donor, at least one selected from the group consisting of a donor metal, donor metal compound and donor metal complex can be used.

Examples of the compounds used for the donor metal, donor metal compound and donor metal complex are compounds disclosed in Patent Application Number PCT/JP2010/003434.

### Fourth Exemplary Embodiment

In a fourth exemplary embodiment, an anode, a plurality of emitting layers, an electron transporting zone that includes a blocking layer adjacent to one of the emitting layers and an electron injecting layer adjacent to the blocking layer, and a cathode are provided in sequential order. A charge blocking layer is provided between two emitting layers of the plurality of the emitting layers. The emitting layers in contact with the charge blocking layer are fluorescent emitting layers. The fluorescent emitting layer, and the blocking layer and the electron injecting layer in the electron transporting zone satisfy the above requirements.

As a configuration of a suitable organic EL device according to the fourth exemplary embodiment, there can be given a configuration as disclosed in Japanese Patent No. 4134280, US Patent Publication US2007/0273270A1 and International Publication WO2008/023623A1. Specifically, the configuration in which an anode, a first emitting layer, a charge blocking layer, a second emitting layer and a cathode are sequentially stacked, and an electron-transporting zone having a blocking layer and an electron injecting layer for preventing diffusion of triplet excitons is further provided between the second emitting layer and the cathode. Here, the charge blocking layer means a layer to control the carrier injection to an emitting layer and the carrier balance between electrons and holes injected in the emitting layer by providing an energy barrier of an HOMO level or an LUMO level between adjacent emitting layers

Specific examples of such a configuration are given below.

anode/first emitting layer/charge blocking layer/second emitting layer/electron transporting zone/cathode

anode/first emitting layer/charge blocking layer/second emitting layer/third emitting layer/electron transporting zone/cathode

It is preferred that a hole transporting zone is provided between the anode and the first emitting layer in the same manner as in other embodiments

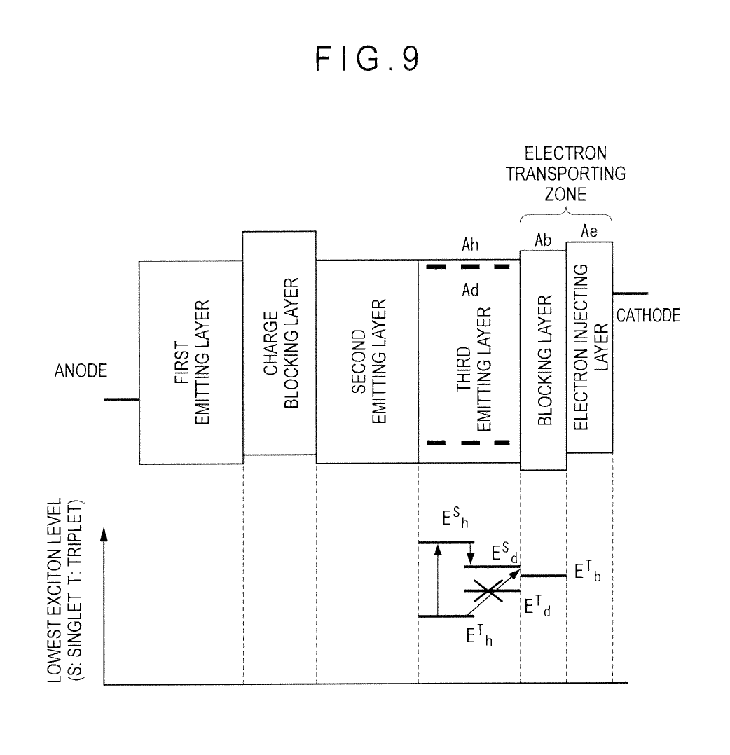

FIG. 9 shows one example of an organic EL device according to the fourth exemplary embodiment. An upper view in FIG. 9 shows a device configuration, and the HOMO and LUMO energy levels of each layer. A lower view in FIG. 9 shows a relationship between energy gaps of the third emitting layer and the blocking layer. The upper view in FIG. 9 shows the relationship in the case of Aₕ>A_{b}>Aₑ.

The organic EL device includes the anode, first emitting layer, second emitting layer, third emitting layer, electron transporting zone, and cathode in sequential order. A charge blocking layer is interposed between the first and second emitting layers. The electron transporting zone is formed of the blocking layer. This blocking layer and third emitting layer are the blocking layer and the fluorescent emitting layer that satisfy the requirements of the invention. The first and second emitting layers may be either a fluorescent emitting layer or a phosphorescent emitting layer.

The device of this embodiment is suitable as a white emitting device. The device can be a white emitting device by adjusting the emission colors of the first emitting layer, second emitting layer and third emitting layer. Moreover, the device can be a white emitting device by arranging only the first emitting layer and the second emitting layer and adjusting the emission colors of these two emitting layers. In this case, the second emitting layer is a fluorescent emitting layer satisfying the requirements of the invention.

In particular, by using a hole transporting material as the host in the first emitting layer, by adding a fluorescent emitting dopant of which the main peak wavelength is larger than 550 nm, by using an electron transporting material as the host in the second emitting layer (and the third emitting layer), and by adding a fluorescent emitting dopant of which the main peak wavelength is equal to or smaller than 550 nm, it is possible to achieve a white emitting device that exhibits a higher luminous efficiency as compared with conventional white emitting devices, even though all of them are entirely formed of fluorescent materials.

Reference is made particularly to a hole transporting layer which is adjacent to the emitting layer. In order to allow the TTF phenomenon of the invention to occur effectively, it is preferred that the triplet energy of the hole transporting material is larger than the triplet energy of the host, when the triplet energy of the hole transporting material and that of the host are compared.

### Fifth Exemplary Embodiment

In a fifth exemplary embodiment, a blue pixel, a green pixel and a red pixel are arranged in parallel on a substrate. Of these three color pixels, at least one of the blue pixel and the green pixel has the configuration of the first exemplary embodiment or second exemplary embodiment.

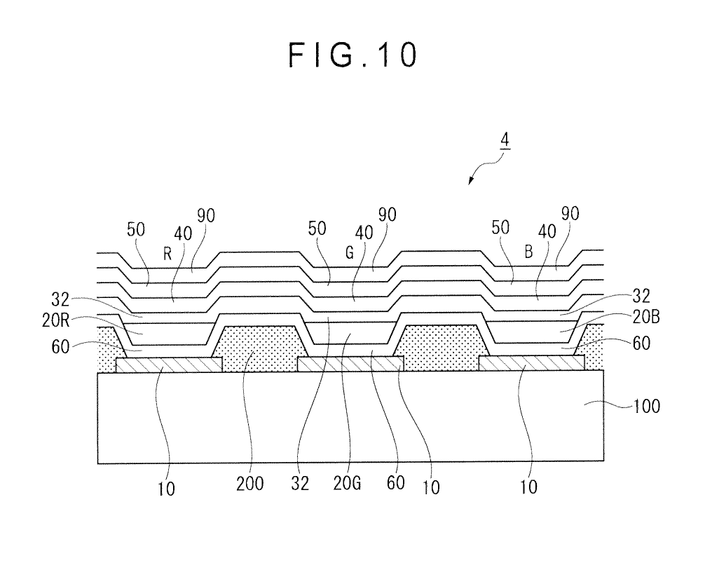

FIG. 10 shows one example of an organic EL device according to the fifth exemplary embodiment.

In a top-emission type organic EL device 4 shown in FIG. 10, a blue pixel B, a green pixel G and a red pixel R are arranged in parallel on a common substrate 100.

The blue pixel B includes the anode 10, the hole transporting zone 60, a blue emitting layer 20B, the blocking layer 32, the electron injecting layer 40, the cathode 50, and a protection layer 90 on the substrate 100 in sequential order.

The green pixel G includes the anode 10, the hole transporting zone 60, a green emitting layer 20G, the blocking layer 32, the electron injecting layer 40, the cathode 50, and the protection layer 90 on the substrate 100 in sequential order.

The red pixel R includes the anode 10, the hole transporting zone 60, a red emitting layer 20R, the blocking layer 32, the electron injecting layer 40, the cathode 50, and the protection layer 90 on the substrate 100 in sequential order.

An insulating film 200 is formed between the anodes of adjacent pixels so as to keep the insulation between the pixels. The electron transporting zone is formed of the blocking layer 32 and the electron injecting layer 40:

In the organic EL device 4, the blocking layer is provided as a common blocking layer for the blue pixel B, the red pixel R and the green pixel G.

The advantageous effects brought by the blocking layer are outstanding comparing to the luminous efficiency conventionally attained in a blue fluorescent device. In a green fluorescent device and a red fluorescent device, similar advantageous effects, such as confining triplet energies in the emitting layer, can be attained, and improvement in luminous efficiency can also be expected.

On the other hand, in a phosphorescent emitting layer, it is possible to attain the advantageous effects of confining triplet energies in the emitting layer, and as a result, diffusion of triplet energies is prevented, thereby contributing to improvement in luminous efficiency of a phosphorescent dopant.

The hole transporting zone is formed of, for instance, a hole transporting layer, or a combination of a hole transporting layer and a hole injecting layer. A common hole transporting zone may be provided or different hole transporting zones may be provided for the blue pixel B, the red pixel R and the green pixel G. Typically, the hole transporting zones respectively have a configuration suited to the color of emitted light.

The configuration of the organic layer formed of the emitting layers 20B, G and R and the blocking layer is not limited to that shown in the figure and is changeable appropriately.

The host and dopant that can be used in the invention are described above. In particular, each color emitting layer will be described below.

A green emitting layer is preferably formed of the following host material and dopant material.

The host material is preferably a fused aromatic ring derivative. As the fused aromatic ring derivative, an anthracene derivative, pyrene derivative and the like are more preferable in view of luminous efficiency and luminous lifetime.

The host material is exemplified by a heterocycle-containing compound. Examples of the heterocycle-containing compound are a carbazole derivative, dibenzofuran derivative, ladder-type furan compound and pyrimidine derivative.

The dopant material is not limited so long as it functions as a dopant, but an aromatic amine derivative is preferable in view of luminous efficiency and the like. As the aromatic amine derivative, a fused aromatic ring derivative having a substituted or unsubstituted arylamino group is preferable. Examples of such a compound are pyrene, anthracene and chrysene having an arylamino group.

A styrylamine compound is also preferable as the dopant material. Examples of the styrylamine compound are styrylamine, styryldiamine, styryltriamine and styryltetraamine. Here, the styrylamine means a compound in which a substituted or unsubstituted arylamine is substituted with at least one arylvinyl group. The arylvinyl group may be substituted with a substituent such as an aryl group, silyl group, alkyl group, cycloalkyl group, or arylamino group, which may have a further substituent.

Furthermore, as the dopant material, a boron complex and a fluoranthene compound are preferable. A metal complex is also preferable as the dopant material. The metal complex is exemplified by an iridium complex or a platinum complex.

A red emitting layer is preferably formed of the following host material and dopant material. The host material is preferably a fused aromatic ring derivative. As the fused aromatic ring derivative, a naphthacene derivative, pentacene derivative and the like are more preferable in view of luminous efficiency and luminous lifetime. The host material is exemplified by a fused polycyclic aromatic compound.

Examples of the fused polycyclic aromatic compound are a naphthalene compound, phenanthrene compound and fluoranthene compound.

The dopant material is preferably an aromatic amine derivative. As the aromatic amine derivative, a fused aromatic ring derivative having a substituted or unsubstituted arylamino group is preferable. Such a compound is exemplified by periflanthene having an arylamino group.

A metal complex is also preferable as the dopant material. The metal complex is exemplified by an iridium complex or platinum complex.

The organic EL device of the fifth exemplary embodiment is prepared in the following manner.

On a substrate, an APC (Ag—Pd—Cu) layer as a silver alloy layer (reflective layer) and a transparent conductive layer such as a zinc oxide (IZO) film and a tin oxide film are sequentially formed. Next, by a typical lithographic technology, this conductive material layer is patterned by etching using a mask with a resist pattern, thereby forming an anode. Then, by the spin coating method, an insulating film formed of a photosensitive resin such as a polyimide is formed by coating on the anode. Thereafter, the resulting film is exposed, developed and cured to allow the anode to be exposed, whereby the anodes for a blue emitting region, a green emitting region and a red emitting region are patterned.

There are three types of electrodes, i.e. an electrode for the red pixel, an electrode for the green pixel and an electrode for a blue pixel. They respectively correspond to the blue emitting region, the green emitting region and the red emitting region, and respectively correspond to the anode. After conducting cleaning for 5 minutes in isopropyl alcohol, a UV ozone cleaning is conducted for 30 minutes. When the hole injecting layer and the hole transporting layer are formed thereafter, the hole injecting layer is stacked over the entire surface of the substrate, and the hole transporting layer is stacked thereon. Emitting layers are formed so as to be correspondingly arranged to the positions of the anode for the red pixel, the anode for the green pixel and the anode for the blue pixel When vacuum evaporation method is used, the blue emitting layer, the green emitting layer and the red emitting layer are finely patterned by using a shadow mask.

Next, a blocking layer is stacked over the entire surface. Subsequently, an electron injecting layer is stacked over the entire surface. Thereafter, Mg and Ag are formed into a film by evaporation, thereby forming a semi-transparent cathode formed of an Mg—Ag alloy.

As for the other members used in the invention, such as the substrate, the anode, the cathode, the hole injecting layer and the hole transporting layer, known members disclosed in PCT/JP2009/053247, PCT/JP2008/073180, U.S. patent application Ser. No. 12/376,236, U.S. patent application Ser. No. 11/766,281, U.S. patent application Ser. No. 12/280,364 or the like can be appropriately selected and used.

It is preferred that the hole transporting layer include an aromatic amine derivative represented by any one of the following formulae (a-1) to (a-5).

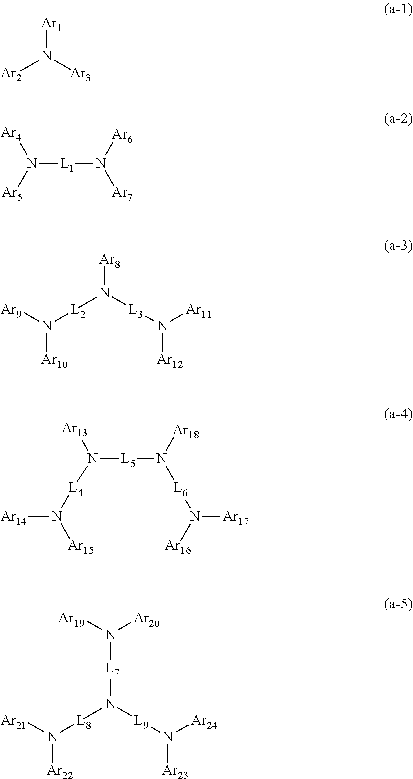

In the formulae (a-1) to (a-5), Ar¹ to Ar²⁴ are independently a substituted or unsubstituted aryl group having 6 to 50 ring carbon atoms, or a substituted or unsubstituted heteroaryl group having 5 to 50 ring atoms.

L¹ to L⁹ are independently a substituted or unsubstituted arylene group having 6 to 50 ring carbon atoms or a substituted or unsubstituted heteroarylene group having 5 to 50 ring atoms.

Examples of a substituent which Ar¹ to Ar²⁴ and L¹ to L⁹ may have include a linear or branched alkyl group having 1 to 15 carbon atoms, a cycloalkyl group having 3 to 15 ring carbon atoms, a trialkylsilyl group having a linear or branched alkyl group having 1 to 15 carbon atoms, a triarylsilyl group having an aryl group having 6 to 14 ring carbon atoms, an alkylarylsilyl group having a linear or branched alkyl group having 1 to 15 carbon atoms and an aryl group having 6 to 14 ring carbon atoms, an aryl group having 6 to 50 ring carbon atoms, a heteroaryl group having 5 to 50 ring atoms, a halogen atom, and a cyano group. Adjacent substituents may bond to each other to form a saturated or unsaturated divalent group forming a ring.

At least one of the above Ar¹ to Ar²⁴ is preferably a substituent represented by the following formula (a-6) or (a-7).

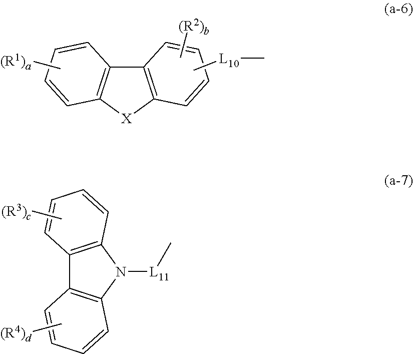

In the formula (a-6), X is an oxygen atom, sulfur atom or N—Ra. Ra is a linear or branched alkyl group having 1 to 15 carbon atoms, a cycloalkyl group having 3 to 15 ring carbon atoms, an aryl group having 6 to 50 ring carbon atoms or a heteroaryl group having 5 to 50 ring atoms.

L₁₀ is a single bond, a substituted or unsubstituted arylene group having 6 to 50 ring carbon atoms, or a substituted or unsubstituted heteroarylene group having 5 to 50 ring atoms.

In the formula (a-7), L₁₁ is a substituted or unsubstituted arylene group having 6 to 50 ring carbon atoms, or a substituted or unsubstituted heteroarylene group having 5 to 50 ring atoms.

In the formulae (a-6) and (a-7), R′ to R⁴ are independently a linear or branched alkyl group having 1 to 15 carbon atoms, a cycloalkyl group having 3 to 15 ring carbon atoms, a trialkylsilyl group having a linear or branched alkyl group having 1 to 15 carbon atoms, a triarylsilyl group having an aryl group having 6 to 14 ring carbon atoms, an alkylarylsilyl group having a linear or branched alkyl group having 1 to 15 carbon atoms and an aryl group having 6 to 14 ring carbon atoms, an aryl group having 6 to 14 ring carbon atoms, a heteroaryl group having 5 to 50 ring atoms, a halogen atom, or a cyano group. Adjacent groups of R¹s to R⁴s may bond to each other to form a ring. a, c and d are each an integer of 0 to 4. b is an integer of 0 to 3.

The compound represented by the formula (a-1) is preferably a compound represented by the following formula (a-8).

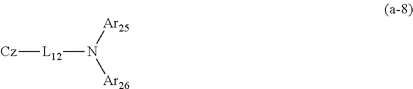

In the formula (a-8), Cz is a substituted or unsubstituted carbazolyl group.

L₁₂ is a substituted or unsubstituted arylene group having 6 to 50 ring carbon atoms, or a substituted or unsubstituted heteroarylene group having 5 to 50 ring atoms.

Ar₂₅ and Ar₂₆ are independently a substituted or unsubstituted aryl group having 6 to 50 ring carbon atoms or a substituted or unsubstituted heteroaryl group having 5 to 50 ring atoms.

The compound represented by the formula (a-8) is preferably a compound represented by the following formula (a-9).

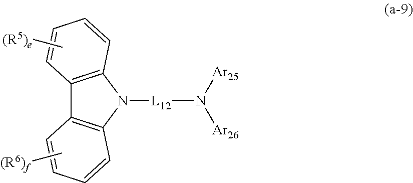

In the formula (a-9), R⁵ to R⁶ are independently a linear or branched alkyl group having 1 to 15 carbon atoms, a cycloalkyl group having 3 to 15 ring carbon atoms, a trialkylsilyl group having a linear or branched alkyl group having 1 to 15 carbon atoms, a triarylsilyl group having an aryl group having 6 to 14 ring carbon atoms, an alkylarylsilyl group having a linear or branched alkyl group having 1 to 15 carbon atoms and an aryl group having 6 to 14 ring carbon atoms, an aryl group having 6 to 14 ring carbon atoms, a heteroaryl group having 5 to 50 ring atoms, a halogen atom, or a cyano group. Adjacent groups of R⁵s to R⁶s may bond to each other to form a ring. e and f are each an integer of 0 to 4.

L₁₂, Ar₂₅ and Ar₂₆ are the same as L₁₂, Ar₂₅ and Ar₂₆ in the formula (a-8).)

The compound represented by the formula (a-9) is preferably a compound represented by the following formula (a-10).

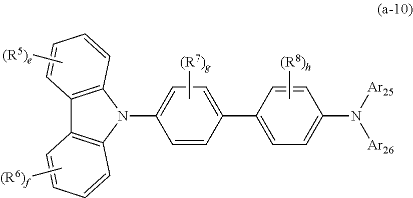

In the formula (a-10), R⁷ and R⁸ are independently a linear or branched alkyl group having 1 to 15 carbon atoms, a cycloalkyl group having 3 to 15 ring carbon atoms, a trialkylsilyl group having a linear or branched alkyl group having 1 to 15 carbon atoms, a triarylsilyl group having an aryl group having 6 to 14 ring carbon atoms, an alkylarylsilyl group having a linear or branched alkyl group having 1 to 15 carbon atoms and an aryl group having 6 to 14 ring carbon atoms, an aryl group having 6 to 14 ring carbon atoms, a heteroaryl group having 5 to 50 ring atoms, a halogen atom, or a cyano group. Adjacent groups of R⁵s to R⁶s may bond to each other to form a ring.

g and h are each an integer of 0 to 4.

R⁵, R⁶, e, f, Ar₂₅ and Ar₂₆ are the same as R⁵, R⁶, e, f, Ar₂₅ and Ar₂₆ in the formula (a-9).

### EXAMPLES

Examples of the invention will be described below. However, the invention is not limited by these Examples.

Materials used in Examples and Comparatives will be shown below.

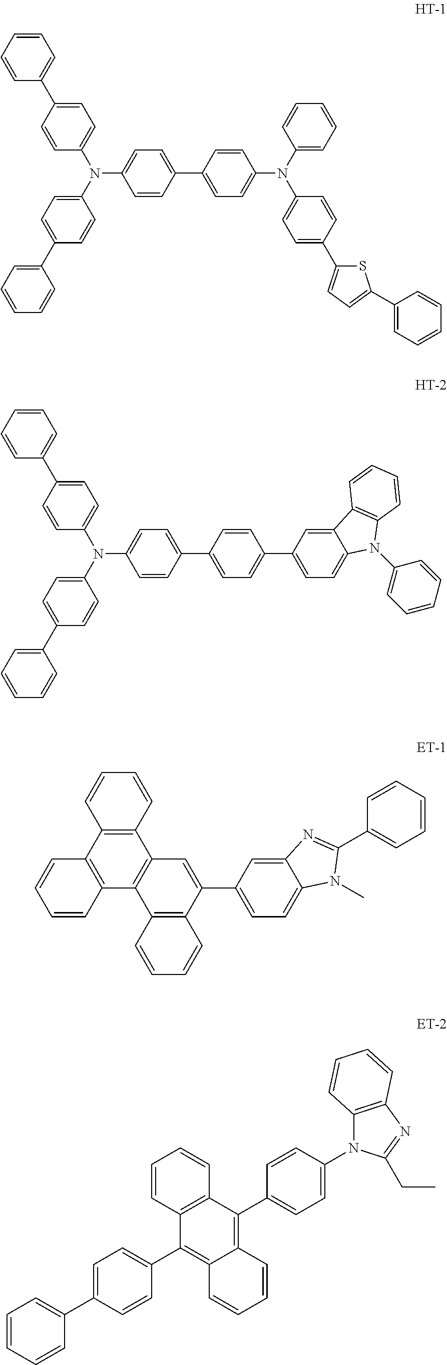

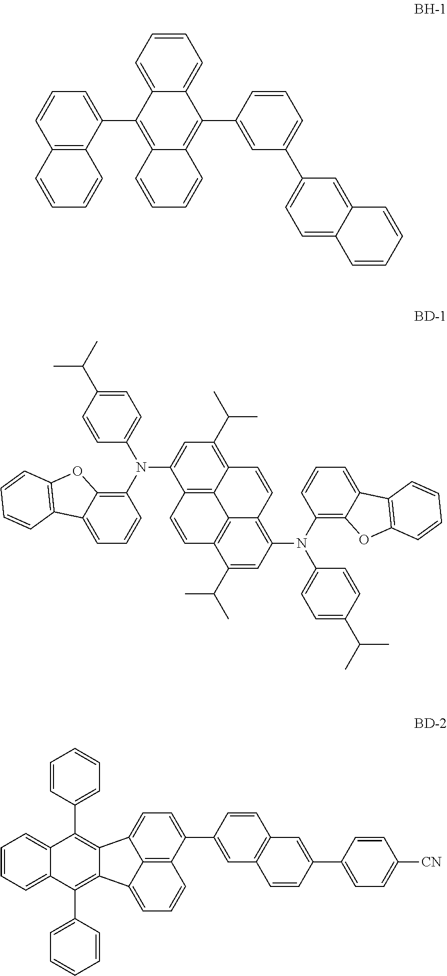

Triplet energies of the compounds BH-1, BD-1 and BD-2 shown above are as follows. A measurement method will be described later.

BH-1 Eg^{T}:1.83 eV

BD-1 Eg^{T}:1.94 eV

BD-2 Eg^{T}:2.13 eV

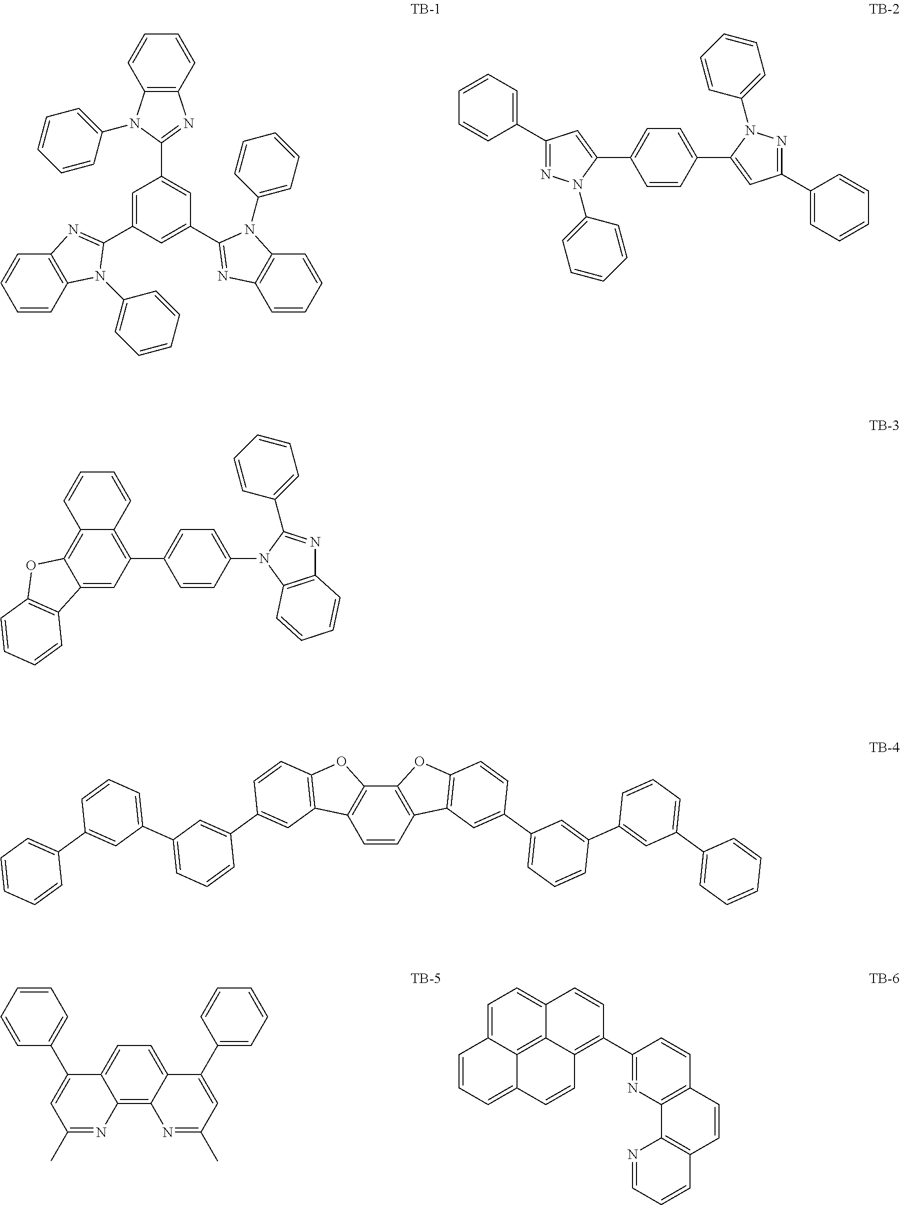

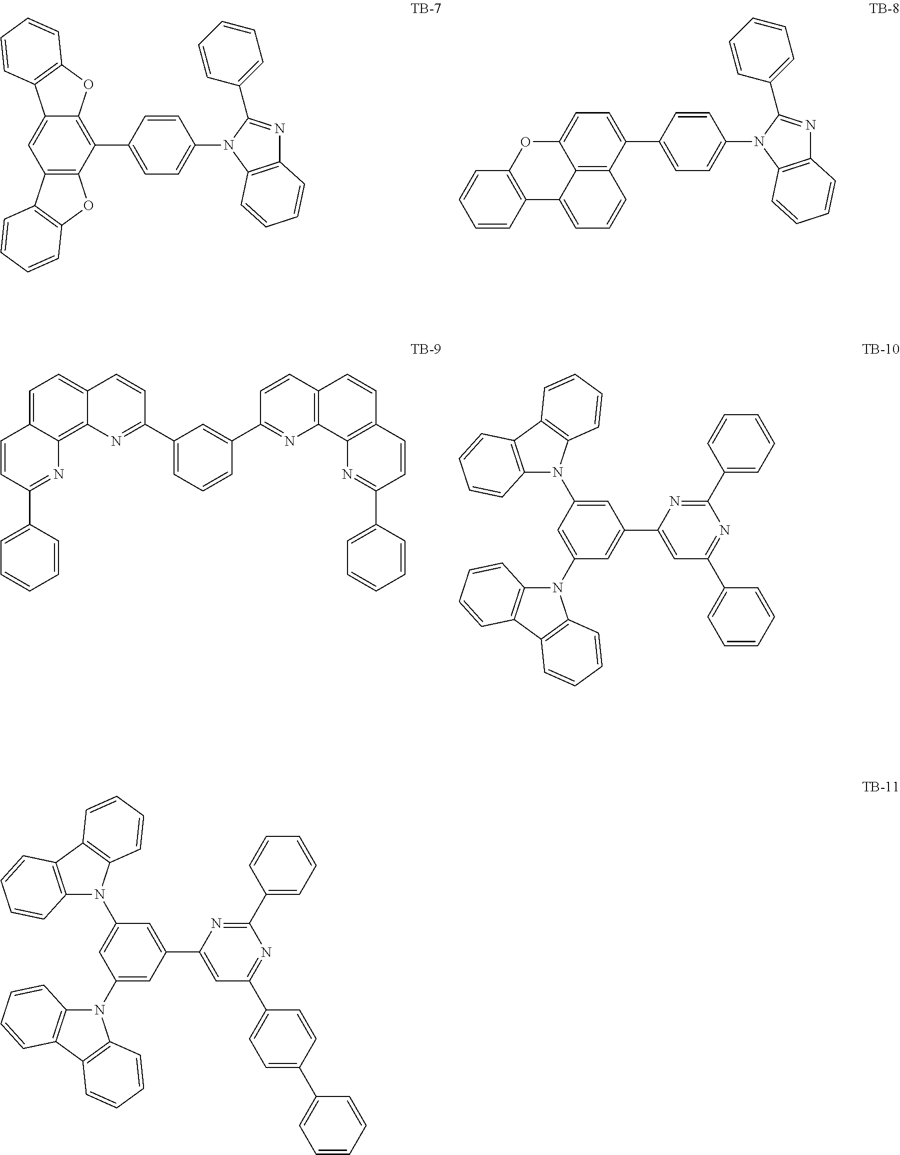

Measuring methods of the above physical properties of the materials are shown below.

### (1) Triplet Energy (E^{T})

A commercially-available measuring machine F-4500 (manufactured by Hitachi, Ltd.) was used for the measurement. The E^{T} conversion equation is as follows.

The conversion equation: E^{T}(eV)=1239.85/λ_{edge}

When the phosphorescence spectrum is expressed in coordinates of which the vertical axis indicates the phosphorescence intensity and of which the horizontal axis indicates the wavelength, and a tangent is drawn to the rise of the phosphorescence spectrum on the shorter wavelength side, “λ_{edge}” is a wavelength value at the intersection of the tangent and the horizontal axis. unit: nm

### (2) Electron Mobility

An electron mobility was evaluated using the impedance spectrometry. Al as the anode, the blocking layer material, LiF, and Al as the cathode were sequentially stacked on the substrate to prepare an electron-only device. DC voltage on which AC voltage of 100 mV was placed was applied thereon, and their complex modulus values were measured. When the frequency at which the imaginary part of the modulus was maximum was set to fₘₐₓ (Hz), a response time T(sec.) was calculated based on the equation T=1/2/π/fₘₐₓ. Using this value, the dependence property of electron mobility on electric field intensity was determined.

### (3) Ionization Potential

A photoelectron spectroscopy (AC-1, manufactured by Riken Keiki Co., Ltd.) was used for the measurement under atmosphere. Specifically, a material was irradiated with light and the amount of electrons generated by charge separation was measured.

### (4) Affinity

An affinity was calculated from measured values of an ionization potential Ip and an energy gap Eg. The calculation equation is as follows.

Af=Ip−Eg

The Energy gap was measured based on an absorption edge of an absorption spectrum in benzene. Specifically, an absorption spectrum was measured with a commercially available ultraviolet-visible spectrophotometer. The energy gap was calculated from a wavelength at which the spectrum began to rise.

### [Physical Properties of Compounds]

Electron mobilities of the above compounds TB-10 to TB-11 and Alq were measured. The results are shown in Table 1.

TABLE 1

| Compound | Electron Mobility (cm²/Vs) |
|---|---|
| TB-10 | 1.4 × 10⁻⁵ |
| TB-11 | 5.0 × 10⁻⁵ |
| Alq | 5.0 × 10⁻⁸ |

Triplet energies of the compounds used for the blocking layer are shown as T1TB in Tables 2 and 3.

Affinities of the compounds used for the blocking layer and the electron injecting layer are respectively shown as AfBT and AfET in Tables 2 and 3. Values obtained by subtracting the affinities of the compounds used for the blocking layer from the affinities of the compounds used for the electron injecting layer are shown as δ(AfET−AfTB) in Tables 2 and 3.

The organic EL devices were prepared in the following manner and evaluated.

### Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum evaporation apparatus. Initially, a compound HT-1 was deposited on a surface of the glass substrate where the transparent electrode line was provided so as to cover the transparent electrode, thereby forming a 50-nm thick film of the compound HT-1. The HT1 film serves as a hole injecting layer.

After the film formation of the HT-1 film, a compound HT-2 was deposited on the HT-1 film to form a 45-nm thick HT-2 film on the HT-1 film. The HT-2 film serves as a hole transporting layer.

Then, a compound BH-1 (host material) and a compound BD-1 (dopant material) (mass ratio of BH-1 to BD-1 was 20:1) were co-evaporated on the HT-2 film to form an emitting layer of 25 nm thickness.

TB-1 was deposited on this emitting layer to form a blocking layer of 5 nm thickness.

ET-1 (electron transporting material) was deposited on the blocking layer to form an electron injecting layer of 20 nm thickness.

LiF was deposited on the electron injecting layer to form a 1-nm thick LiF film.

A metal Al was deposited on the LiF film to form a 150-nm thick metal cathode.

Thus, the organic EL device of Example 1 was prepared.

### Examples 2 to 10 and Comparatives 1 to 6

Except that the compounds shown in Table 1 were used as the dopant of the emitting layer and the compounds of the blocking layer and the electron injecting layer, the organic EL devices were prepared in the same manner as in the Example 1.

### [Evaluation of Organic EL Devices]

The prepared organic EL devices were evaluated as below. The results are shown in Table 1.

### Initial Performance

A voltage was applied on the organic EL devices such that a current density was 10 mA/cm², where a value of the voltage was measured. EL spectra were measured with a spectral radiance meter (CS-1000, manufactured by KONICA MINOLTA). Chromaticity CIEₓ, CIE_{y}, current efficiency L/J (cd/A), external quantum efficiency EQE (%), and main peak wavelength λₚ (nm) were calculated from the obtained spectral-radiance spectra.

TABLE 2

| | Material | | | | | | | | | | | | |
|---|---|---|---|---|---|---|---|---|---|---|---|---|---|
| | | | Electron | | | | | | | | | | δ(AfET − |
| | Dopant | Blocking | Injecting | Voltage | Chromaticity CIE | | L/J | EQE | λp | TITB | AfET | AfTB | AfTB) |
| | (BD) | Layer (TB) | Layer (ET) | V | x | y | cd/A | % | nm | eV | eV | eV | eV |
| Example 1 | BD-1 | TB-1 | ET-1 | 4.0 | 0.132 | 0.133 | 10.9 | 10.0 | 464 | 2.80 | 2.44 | 2.71 | −0.27 |
| Example 2 | BD-1 | TB-2 | ET-1 | 4.0 | 0.131 | 0.131 | 10.8 | 10.1 | 464 | 2.71 | 2.44 | 2.80 | −0.36 |
| Example 3 | BD-1 | TB-3 | ET-1 | 4.3 | 0.132 | 0.128 | 10.6 | 10.1 | 463 | 2.60 | 2.44 | 2.60 | −0.16 |
| Example 4 | BD-1 | TB-4 | ET-1 | 4.5 | 0.133 | 0.114 | 8.76 | 9.00 | 462 | 2.85 | 2.44 | 2.46 | −0.02 |
| Example 5 | BD-1 | TB-5 | ET-1 | 4.8 | 0.132 | 0.133 | 10.6 | 9.82 | 464 | 2.50 | 2.44 | 3.20 | −0.76 |
| Example 6 | BD-1 | TB-6 | ET-1 | 4.6 | 0.132 | 0.131 | 10.6 | 9.86 | 463 | 2.08 | 2.44 | 2.70 | −0.26 |
| Example 7 | BD-2 | TB-7 | ET-1 | 3.6 | 0.145 | 0.112 | 10.0 | 10.0 | 450 | 2.79 | 2.44 | 2.65 | −0.21 |
| Example 8 | BD-2 | TB-8 | ET-1 | 3.6 | 0.144 | 0.113 | 10.1 | 10.0 | 451 | 2.22 | 2.44 | 2.73 | −0.29 |
| Example 9 | BD-2 | TB-9 | ET-1 | 4.3 | 0.145 | 0.119 | 10.2 | 9.70 | 451 | 2.60 | 2.44 | 2.84 | −0.40 |
| Example 10 | BD-2 | TB-9 | ET-2 | 3.8 | 0.144 | 0.118 | 10.4 | 9.95 | 451 | 2.60 | 2.99 | 2.84 | 0.15 |
| Comparative 1 | BD-1 | TB-1 | ET-2 | 5.0 | 0.131 | 0.135 | 8.05 | 7.40 | 464 | 2.80 | 2.99 | 2.71 | 0.28 |
| Comparative 2 | BD-1 | TB-2 | ET-2 | 5.7 | 0.131 | 0.134 | 7.53 | 6.93 | 464 | 2.71 | 2.99 | 2.76 | 0.23 |
| Comparative 3 | BD-1 | TB-3 | ET-2 | 5.9 | 0.131 | 0.127 | 6.67 | 6.36 | 463 | 2.60 | 2.99 | 2.60 | 0.39 |
| Comparative 4 | BD-1 | TB-4 | ET-2 | 6.2 | 0.134 | 0.111 | 4.76 | 4.99 | 462 | 2.85 | 2.99 | 2.46 | 0.53 |
| Comparative 5 | BD-2 | TB-7 | ET-2 | 4.8 | 0.145 | 0.102 | 5.24 | 5.62 | 449 | 2.79 | 2.99 | 2.65 | 0.34 |
| Comparative 6 | BD-2 | TB-8 | ET-2 | 5.1 | 0.145 | 0.099 | 4.32 | 4.76 | 450 | 2.22 | 2.99 | 2.73 | 0.26 |

In the organic EL devices of Examples 1 to 10, the triplet energy of the blocking layer was larger than triplet energy of the host and a value obtained by subtracting the affinity of the blocking layer from the affinity of the electron injecting layer was 0.15 eV or less. As a result, the electrons were favorably supplied from the cathode and the carrier balance was improved, so that a high external quantum efficiency was obtained.

On the other hand, in the organic EL devices of Comparatives 1 to 6, a value obtained by subtracting the affinity of the blocking layer from the affinity of the electron injecting layer was 0.2 eV or more. As a result, the electrons were not sufficiently supplied from the cathode, and the carrier balance was not met, so that the obtained external quantum efficiency was lower than those of Examples 1 to 10.

### Example 11

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum evaporation apparatus. Initially, a compound HT-1 was evaporated on a surface of the glass substrate where the transparent electrode line was provided so as to cover the transparent electrode, thereby forming a 50-nm thick film of the compound HT1. The HT1 film serves as a hole injecting layer.

After the film formation of the HT-1 film, a compound HT-2 was deposited on the HT-1 film to form a 45-nm thick HT-2 film on the HT-1 film. The HT-2 film serves as a hole transporting layer.

Then, a compound BH-1 (host material) and a compound BD-1 (dopant material) (mass ratio of BH-1 to BD-1 was 20:1) were co-evaporated on the HT-2 film to form an emitting layer of 25 nm thickness.

TB-10 was deposited on this emitting layer to form a blocking layer of 5 nm thickness.

ET-2 (electron transporting material) was deposited on the blocking layer to form a electron injecting layer of 20 nm thickness.

LiF was deposited on the electron injecting layer to form a 1-nm thick LiF film.

A metal Al was deposited on the LiF film to form a 150-nm thick metal cathode.

Thus, the organic EL device of Example 11 was prepared.

### Examples 12 to 13

Except that the compounds shown in Table 2 were used as the compounds of the blocking layer and the electron injecting layer, the organic EL devices were prepared in the same manner as in the Example 11.

TABLE 3

| | Material | | | | | | | | | | | | |
|---|---|---|---|---|---|---|---|---|---|---|---|---|---|
| | | | Electron | | | | | | | | | | δ(AfET − |
| | Dopant | Blocking | Injecting | Voltage | Chromaticity CIE | | L/J | EQE | λp | TITB | AfET | AfTB | AfTB) |
| | (BD) | Layer (TB) | Layer (ET) | V | x | y | cd/A | % | nm | eV | eV | eV | eV |
| Example 11 | BD-1 | TB-10 | ET-2 | 3.8 | 0.131 | 0.131 | 11.5 | 10.7 | 464 | 2.90 | 2.99 | 2.50 | 0.49 |
| Example 12 | BD-1 | TB-10 | ET-1 | 4.1 | 0.132 | 0.128 | 10.8 | 10.3 | 463 | 2.90 | 2.44 | 2.50 | −0.06 |
| Example 13 | BD-1 | TB-11 | ET-2 | 3.86 | 0.132 | 0.138 | 10.09 | 9.04 | 464 | 2.65 | 2.99 | 2.62 | 0.37 |

In the organic EL devices of Examples 11 to 13, when the compounds having an azine ring (i.e., TB-10 and TB-11) were used in the blocking layer, the organic EL devices of Examples 11 to 13 each exhibited an external quantum efficiency that was equivalent to those of the organic EL devices in Examples 1 to 10 and higher than those of the organic EL devices in Comparatives 1 to 6. The reason that the organic EL devices of Examples 11 and 13 exhibited a high external quantum efficiency although having a value of δ(AfET−AfTB) larger than 0.2 eV is that the compounds having an azine ring were unlikely to vulnerable to the energy barrier even when the energy barrier existed between the blocking layer the electron injecting layer, so that the amount of the electrons supplied to the emitting layer was hardly decreased.

What is claimed is:

1. An organic electroluminescence device comprising an anode, an emitting layer, a blocking layer, an electron injecting layer, and a cathode in sequential order, wherein
the emitting layer comprises a host and a dopant,
the blocking layer comprises an aromatic heterocyclic derivative,
a triplet energy E^{T}_{b} (eV) of the aromatic heterocyclic derivative is larger than a triplet energy E^{T}ₕ (eV) of the host, and
an affinity A_{b} (eV) of the blocking layer and an affinity A, (eV) of the electron injecting layer satisfy a relationship of Aₑ−A_{b}<0.2.

2. The organic electroluminescence device according to claim 1, wherein
the triplet energy E^{T}_{b} (eV) of the aromatic heterocyclic derivative and the triplet energy E^{T}ₕ (eV) of the host satisfy a relationship of E^{T}ₕ+0.2<E^{T}_{b}

3. The organic electroluminescence device according to claim 1, wherein
the triplet energy E^{T}_{b} (eV) of the aromatic heterocyclic derivative and the triplet energy E^{T}ₕ (eV) of the host satisfy a relationship of E^{T}ₕ+0.3<E^{T}_{b}

4. The organic electroluminescence device according to claim 1, wherein
the triplet energy E^{T}_{b} (eV) of the aromatic heterocyclic derivative and the triplet energy E^{T}ₕ (eV) of the host satisfy a relationship of E^{T}ₕ+0.4<E^{T}_{b}

5. The organic electroluminescence device according to claim 1, wherein
the aromatic heterocyclic derivative included in the blocking layer has six or more cyclic structures, and
the triplet energy E^{T}_{b} (eV) of the aromatic heterocyclic derivative having the six or more cyclic structures is larger than the triplet energy E^{T}ₕ (eV) of the host.

6. The organic electroluminescence device according to claim 1, wherein
the triplet energy E^{T}_{b} (eV) of the aromatic heterocyclic derivative and a triplet energy E^{T}_{Alq} (eV) of tris(8-quinolinolato)aluminum complex satisfy a relationship of E^{T}_{b}>E^{T}_{Alq}.

7. The organic electroluminescence device according to claim 1, wherein
an electron mobility of the aromatic heterocyclic derivative is 10⁻⁶ cm²/Vs or more in an electric field intensity of 0.04 MV/cm to 0.5 MV/cm.

8. The organic electroluminescence device according to claim 1, wherein
an electron mobility of a material for forming the electron injecting layer is 10⁻⁶ cm²/Vs or more in an electric field intensity of 0.04 MV/cm to 0.5 MV/cm.

9. The organic electroluminescence device according to claim 1, wherein
the dopant exhibits a fluorescent emission of a main peak wavelength of 550 nm or less, and
a triplet energy E^{T}_{d} (eV) of the dopant is larger than the triplet energy E^{T}ₕ (eV) of the host.

10. The organic electroluminescence device according to claim 1, wherein
a hole transporting zone is provided between the anode and the emitting layer,
a hole transporting layer is adjacent to the emitting layer in the hole transporting zone, and
a triplet energy E^{T}ₕₒ (eV) of the hole transporting layer is larger than the triplet energy E^{T}ₕ (eV) of the host.

11. The organic electroluminescence device according to claim 1, wherein
a material for forming the electron injecting layer is the same as a material for forming the blocking layer.

12. The organic electroluminescence device according to claim 1, wherein
a material for forming the electron injecting layer is the same as a material for forming the blocking layer, and
the electron injecting layer is doped with a donor.

13. The organic electroluminescence device according to claim 1, wherein
the dopant is at least one compound selected from the group consisting of a pyrene derivative, aminoanthracene derivative, aminochrysene derivative, aminopyrene derivative, fluoranthene derivative and boron complex.

14. The organic electroluminescence device according to claim 1, wherein
the host is a compound that contains a double bond only in a cyclic structure.

15. The organic electroluminescence device according to claim 1, wherein
the dopant is a compound that contains a double bond only in a cyclic structure.

16. An organic electroluminescence device comprising an anode, an emitting layer, a blocking layer, an electron injecting layer, and a cathode in sequential order, wherein
the emitting layer comprises a host and a dopant,
the blocking layer comprises an aromatic heterocyclic derivative,
a triplet energy E^{T}_{b} (eV) of the aromatic heterocyclic derivative is larger than a triplet energy E^{T}ₕ (eV) of the host, and
the aromatic heterocyclic derivative has an azine ring.

17. The organic electroluminescence device according to claim 16, wherein
the aromatic heterocyclic derivative is represented by a formula (1) below, 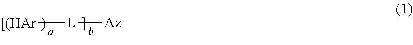
where: HAr represents a substituted or unsubstituted heterocyclic group having 5 to 30 ring atoms, and when a plurality of HAr are present, the plurality of HAr are mutually the same or different;
Az represents a substituted or unsubstituted pyrimidine, a substituted or unsubstituted pyrazine, a substituted or unsubstituted pyridazine, or a substituted or unsubstituted triazine;
L represents a single bond, a divalent to tetravalent residue of a substituted or unsubstituted aromatic hydrocarbon ring having 6 to 30 ring carbon atoms, a divalent to tetravalent residue of a substituted or unsubstituted heterocylic ring having 5 to 30 ring atoms, or a divalent to tetravalent residue formed by combination in a single bond of two to three rings selected from the aromatic hydrocarbon ring and the heterocyclic ring;
a is an integer of 1 to 3; and
b is an integer of 1 to 3.

18. The organic electroluminescence device according to claim 16, wherein
an electron mobility of the aromatic heterocyclic derivative is 10⁻⁶ cm²/Vs or more in an electric field intensity of 0.04 MV/cm to 0.5 MV/cm.

19. The organic electroluminescence device according to claim 16, wherein
the triplet energy E^{T}_{b} (eV) of the aromatic heterocyclic derivative and the triplet energy E^{T}ₕ (eV) of the host satisfy a relationship of E^{T}ₕ+0.2<E^{T}_{b}.

20. The organic electroluminescence device according to claim 16, wherein
the triplet energy E^{T}_{b} (eV) of the aromatic heterocyclic derivative and the triplet energy E^{T}ₕ (eV) of the host satisfy a relationship of E^{T}ₕ+0.3<E^{T}_{b}

21. The organic electroluminescence device according to claim 16, wherein
the triplet energy E^{T}_{b} (eV) of the aromatic heterocyclic derivative and the triplet energy E^{T}ₕ (eV) of the host satisfy a relationship of E^{T}ₕ+0.4<E^{T}_{b}

22. The organic electroluminescence device according to claim 16, wherein
the aromatic heterocyclic derivative included in the blocking layer has six or more cyclic structures, and
the triplet energy E^{T}_{b} (eV) of the aromatic heterocyclic derivative having the six or more cyclic structures is larger than a triplet energy E^{T}ₕ (eV) of the host.

23. The organic electroluminescence device according to claim 16, wherein
an electron mobility of a material for forming the electron injecting layer is 1×10⁻⁶ cm²/Vs or more in an electric field intensity of 0.04 MV/cm to 0.5 MV/cm.

24. The organic electroluminescence device according to claim 16, wherein
the dopant exhibits a fluorescent emission of a main peak wavelength of 550 nm or less, and
a triplet energy E^{T}_{d} (eV) of the dopant is larger than the triplet energy E^{T}ₕ (eV) of the host.

25. The organic electroluminescence device according to claim 16, wherein
a hole transporting zone is provided between the anode and the emitting layer,
a hole transporting layer is adjacent to the emitting layer in the hole transporting zone, and
a triplet energy E^{T}ₕₒ (eV) of the hole transporting layer is larger than the triplet energy E^{T}ₕ (eV) of the host.

26. The organic electroluminescence device according to claim 16, wherein
a material for forming the electron injecting layer is the same as a material for forming the blocking layer.

27. The organic electroluminescence device according to claim 16, wherein
a material for forming the electron injecting layer is the same as a material for forming the blocking layer, and
the electron injecting layer is doped with a donor.

28. The organic electroluminescence device according to claim 16, wherein
the dopant is at least one compound selected from the group consisting of a pyrene derivative, aminoanthracene derivative, aminochrysene derivative, aminopyrene derivative, fluoranthene derivative and boron complex.

29. The organic electroluminescence device according to claim 16, wherein
the host is a compound that contains a double bond only in a cyclic structure.

30. The organic electroluminescence device according to claim 16, wherein
the dopant is a compound that contains a double bond only in a cyclic structure.
